(19) United States
(12) Patent Application Publication
(10) Pub. No.: US 2026/0307168 A1
(43) Pub. Date: Oct. 8, 2026

(54) METHODS OF PATTERNING SUBSTRATES

(71) Applicant: UNIVERSITY OF ROCHESTER, Rochester, NY (US)

(72) Inventors: Alexander SHESTOPALOV, Rochester, NY (US); Patrick RAFFAELLE, Rochester, NY (US)

(21) Appl. No.: 19/481,642

(22) PCT Filed: May 2, 2024
(86) PCT No.: PCT/US2024/027376

§ 371 Date: Nov. 5, 2025

Related U.S. Application Data
(60) Provisional application No. 63/465,012, filed on May 9, 2023.

(51) Int. Cl. B23K 26/0622; H10P 14/692

(52) U.S. Cl. CPC B23K 26/0624; H10P 14/69391

(57) ABSTRACT

Described herein are methods of patterning substrates. For example, disclosed herein are methods comprising: irradiating a portion of a top surface of a substrate with a laser, wherein the laser has a fluence of 0.05-2.5 J/cm² and a wavelength of 190-2500 nm, and the irradiation comprises a laser pulse having a duration of from 200 femtoseconds to 10 nanoseconds. In some examples, the portion irradiated with the laser defines a growth surface and the remaining portion comprises a non-growth surface, or the portion irradiated with the laser defines a non-growth surface and the remaining portion comprises a growth surface; and the method further comprises subsequently depositing a first material on the substrate, wherein the first material selectively deposits on the growth surface relative to the non-growth surface; thereby forming a patterned substrate. Also disclosed herein are patterned substrates made by any of the methods disclosed herein.

### CROSS-REFERENCE TO RELATED APPLICATIONS

This application claims the benefit of priority to U.S. Provisional Application No. 63/465,012 filed May 9, 2023, which is hereby incorporated herein by reference in its entirety.

### STATEMENT OF GOVERNMENT SUPPORT

This invention was made with government support under DE-NA-0003525 awarded by the U.S. Department of Energy. The government has certain rights in the invention.

### BACKGROUND

The total consumption of electricity by opto-electronic devices is predicted to surpass the global energy production by 2050 unless radical changes are made in the efficiency, design, and manufacturing of the device components. The ever-increasing number of the transistors and their continuous miniaturization requires progressively denser microchips that are less efficient, require more power, and face issues associated with thermal management. This trend can be avoided by inventing new manufacturing techniques that open access to new and highly efficient 3D chip designs rather than by relaying on unsustainable scaling. With the future of microelectronics moving beyond Moore's Law, atomically precise manufacturing is becoming a bottleneck in achieving the required degree of device precision. The future generation of atomically precise and ultra-efficient opto-electronic and quantum devices will rely on 3D architectures that are only accessible via bottom-up processes. One of the major challenges of such bottom-up manufacturing that precludes widespread implementation is the lack of unifying conditions and patterning methods that are universally compatible with different materials and device architectures. The methods disclosed herein address these and other needs.

### SUMMARY

In accordance with the purposes of the disclosed methods, as embodied and broadly described herein, the disclosed subject matter relates to methods of patterning substrates.

For example, disclosed herein are methods comprising: irradiating a portion of a top surface of a substrate with a laser; wherein the laser has a fluence of from 0.05 to 2.5 J/cm²; wherein the laser has a wavelength of from 190 nm to 2500 nm; and wherein the irradiation comprises a laser pulse, the pulse having a duration of from 200 femtoseconds to 10 nanoseconds.

In some examples, the portion irradiated with the laser defines a growth surface and the remaining portion (e.g., the non-irradiated portion) comprises a non-growth surface, or wherein the portion irradiated with the laser defines a non-growth surface and the remaining portion (e.g., the non-irradiated portion) comprises a growth surface; and the method further comprises subsequently depositing a first material on the substrate, wherein the first material selectively deposits on the growth surface relative to the non-growth surface; thereby forming a patterned substrate.

In some examples, the method further comprises cleaning and/or etching the substrate prior to irradiation.

In some examples, the method further comprises: irradiating a portion of the patterned substrate with the laser; wherein the portion irradiated with the laser defines a growth surface and the remaining portion (e.g., the non-irradiated portion) comprises a non-growth surface, or wherein the portion irradiated with the laser defines a non-growth surface and the remaining portion (e.g., the non-irradiated portion) comprises a growth surface; and subsequently depositing a second material on the substrate, wherein the second material selectively deposits on the growth surface relative to the non-growth surface. In some examples, the irradiated portion of the patterned substrate comprises the top surface of the substrate. In some examples, the irradiated portion of the patterned substrate comprises the first material. In some examples, the first material and the second material are the same. In some examples, the first material and the second material are different.

In some examples, the non-growth surface is substantially free of the first material and/or the second material.

In some examples, the first material and/or the second material comprises a metal, an oxide such as a metal oxide, an organic resist, a semiconductor, or a combination thereof. In some examples, the organic resist comprises an atomic or molecular resist.

In some examples, depositing the first material and/or the second material comprises chemical vapor deposition (CVD), atomic layer deposition (ALD), or a combination thereof.

In some examples, the irradiated portion is oxidized by the laser.

In some examples, the laser has a fluence of from 0.1 to 1 J/cm², from 0.25 to 0.7 J/cm², or from 0.5 to 0.7 J/cm².

In some examples, the laser has a wavelength of from 250 nm to 1000 nm, from 250 to 750 nm, from 250 to 500 nm, from 300 to 400 nm, or from 325 to 375 nm.

In some examples, the laser has a fluence of from 0.5 to 0.7 J/cm² and a wavelength of from 250 to 500 nm, such as a wavelength of from 325 to 375 nm.

In some examples, the pulse has a duration of from 1 to 10 nanoseconds (ns), from 2 ns to 8 ns, from 3 ns to 7 ns, or from 4 ns to 6 ns.

In some examples, the laser has a fluence of from 0.5 to 0.7 J/cm² and the pulse has a duration of from 1 to 10 nanoseconds.

In some examples, the laser has a wavelength of from 250 nm to 500 nm, such as a wavelength from 325 to 375 nm, and the pulse has a duration of from 1 to 10 nanoseconds.

In some examples, the laser has a fluence of from 0.5 to 0.7 J/cm² and a wavelength of from 250 nm to 500 nm, such as a wavelength from 325 to 375 nm, and the pulse has a duration of from 1 to 10 nanoseconds.

In some examples, the irradiation has an absorption depth of from 1 nm to 10 nm.

In some examples, the irradiation is below the laser-induced damage threshold.

In some examples, the method is performed at a temperature of from 0 to 400° C., from 0° C. to 200° C., from 0° C. to 100° C., or from 10° C. to 50° C. In some examples, the method is performed at room temperature.

In some examples, the substrate has a temperature of from 0 to 400° C., from 0° C. to 200° C., from 0° C. to 100° C., or from 10° C. to 50° C. In some examples, the substrate is at room temperature. In some examples, the temperature of the substrate is not substantially changed by the irradiation (e.g., wherein the irradiation does not substantially heat the substrate).

In some examples, the method is performed under vacuum.

In some examples, the method is performed at a pressure of from 1×10⁻⁷ Pascals (Pa) to 500 Pa. In some examples, the method is performed at a pressure of 1×10⁻⁷ Pa to 0.1 Pa, 1×10⁻⁷ Pa to 1×10⁻³ Pa, or from 1×10⁻⁷ Pa to 1×10⁻⁵ Pa.

In some examples, the method is performed at room temperature and under vacuum.

In some examples, the substrate comprises silicon. In some examples, the substrate comprises Si(100), Si(110), Si(111), or Si(110). In some examples, the substrate comprises Si(100).

In some examples, the top surface of the substrate comprises H—Si(100).

In some examples, the irradiated portion of the top surface of the substrate is oxidized by the laser.

In some examples, the irradiated portion of the top surface of the substrate comprises OH—Si(100).

In some examples, the method further comprises wet chlorination of the substrate before or after irradiation, but before deposition and after cleaning/etching. In some examples, the top surface of the substrate comprises Cl—Si(100). In some examples, the irradiated portion of the top surface of the substrate comprises ClₓO_{y}—Si(100).

In some examples, the method comprises area-selective atomic layer deposition, atomic layer etching, scanning tunneling microscopy (STM), extreme UV lithography, or a combination thereof.

Also disclosed herein are patterned substrates made by any of the methods disclosed herein.

Also disclosed herein are articles of manufacture comprising any of the patterned substrates disclosed herein. In some examples, the article comprises an electronic device, a photonic device, an optical device, an optoelectronic device, or a combination thereof.

Additional advantages will be set forth in part in the description that follows or may be learned by practice of the aspects described below. The advantages described below will be realized and attained by elements and combinations particularly pointed out in the appended claims. It is to be understood that both the foregoing general description and the following detailed description are exemplary and explanatory only and are not restrictive.

### BRIEF DESCRIPTION OF THE FIGURES

The accompanying figures, which are incorporated in and constitute a part of this specification, illustrate several aspects described below.

FIG. 1. Schematic view of the laser-assisted oxidation (LAO) chamber and the laser source.

FIG. 2. Histogram showing the quantitative XPS characterization of a H—Si(100) surface as a function of laser fluence exposure. For each set, from left to right, the laser fluence is 0, 0.22, 0.37, 0.53, 0.61, and 0.68 J/cm². Insets: SEM imaging showing formation of beam profile as laser fluence increases.

FIG. 3. Beam profile and corresponding SEM image of laser exposure site; (right) two images overlayed.

FIG. 4. (Top) SEM imaging of H—Si(100) and OH—Si(100) irradiated sites following laser exposure; (Bottom) SEM imaging of same H—Si(100) and OH—Si(100) sites following ambient exposure for 72 hrs.

FIG. 5. Schematic illustration of methods.

FIG. 6. Schematic illustration of two laser-assisted oxidation pathways to patterned Al₂O₃ deposition.

FIG. 7. Schematic illustrate of Area-Selective Atomic Layer Deposition (AS-ALD).

FIG. 8. Schematic illustration of methods.

FIG. 9. Image of laser patterned Si—Cl substrate.

FIG. 10. XPS analysis of Al₂O₃ content on laser-exposed, unexposed, and control sample.

FIG. 11. Schematic illustration of methods.

FIG. 12. Oxide formation (at %) at different laser fluences.

FIG. 13A. Schematic of laser system setup.

FIG. 13B. SEM imaging of H—Si(100) surfaces post-laser exposure with fluences of; 0.25 J/cm², 0.50 J/cm², and 1.25 J/cm².

FIG. 13C. SiOₓ2p, O 1s, and Si_{Bulk}2p XPS region spectra from H—Si(100) surfaces post-laser exposure with fluences of; 0.10 J/cm², 0.25 J/cm², 0.50 J/cm², and 0.75 J/cm².

FIG. 14A. SEM imaging of (Left) H—Si(100) and (Right) OH—Si(100) surfaces post-exposure with 0.75 J/cm².

FIG. 14B. Plot showing how many times greater the SiOₓ2p and O1s XPS signals (SiOₓ normalized by Si_{Bulk}2p and O 1s normalized by Si2p) are on both OH—Si(100) and H—Si(100) surfaces post laser exposure, relative to an unexposed area on the same surfaces.

FIG. 14C. Plot showing the estimated SiO₂ film thickness calculated using Equation 1.

FIG. 15. Array of greyscale pixel intensity profiles for (Top) SEM imaging of sites (image subsets) matched with (Bottom) fluence maps (image subsets) generated with the corresponding laser fluence.

FIG. 16A. SEM imaging of H—Si(100) surface (Left) immediately following laser exposure, and (Right) after 72 hr in an ambient environment post-exposure.

FIG. 16B. Histogram showing the percent change in SiOₓ2p and O1s XPS signal (SiOₓ normalized by Si_{Bulk}2p and O 1s normalized by Si2p) after 72 hours in an ambient environment of laser exposed sites relative to an unexposed area for both H—Si(100) and OH—Si(100) surfaces.

FIG. 16C. A comparison of SiOₓ2p spectra from a 0.5 J/cm² laser exposed H—Si(100) surface and unexposed H—Si(100) and OH—Si(100) surfaces.

### DETAILED DESCRIPTION

The methods, devices, and compositions described herein may be understood more readily by reference to the following detailed description of specific aspects of the disclosed subject matter and the Examples included therein.

Before the present methods, devices, and compositions are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

In this specification and in the claims that follow, reference will be made to a number of terms, which shall be defined to have the following meanings: Throughout the description and claims of this specification the word “comprise” and other forms of the word, such as “comprising” and “comprises,” means including but not limited to, and is not intended to exclude, for example, other additives, components, integers, or steps.

As used in the description and the appended claims, the singular forms “a,” “an,” and “the” include plural referents unless the context clearly dictates otherwise. Thus, for example, reference to “a composition” includes mixtures of two or more such compositions, reference to “the compound” includes mixtures of two or more such compounds, reference to “an agent” includes mixture of two or more such agents, and the like.

“Optional” or “optionally” means that the subsequently described event or circumstance can or cannot occur, and that the description includes instances where the event or circumstance occurs and instances where it does not.

Values can be expressed herein as an “average” value. “Average” generally refers to the statistical mean value.

By “substantially” is meant within 5%, e.g., within 4%, 3%, 2%, or 1%.

“Exemplary” means “an example of” and is not intended to convey an indication of a preferred or ideal embodiment. “Such as” is not used in a restrictive sense, but for explanatory purposes.

It is understood that throughout this specification the identifiers “first” and “second” are used solely to aid the reader in distinguishing the various components, features, or steps of the disclosed subject matter. The identifiers “first” and “second” are not intended to imply any particular order, amount, preference, or importance to the components or steps modified by these terms.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

References in the specification and concluding claims to parts by weight of a particular element or component in a composition denotes the weight relationship between the element or component and any other elements or components in the composition or article for which a part by weight is expressed. Thus, in a compound containing 2 parts by weight of component X and 5 parts by weight component Y, X and Y are present at a weight ratio of 2:5, and are present in such ratio regardless of whether additional components are contained in the compound.

A weight percent (wt. %) of a component, unless specifically stated to the contrary, is based on the total weight of the formulation or composition in which the component is included.

The term “(co)polymer” includes homopolymers, copolymers, or mixtures thereof.

The term “(meth)acryl . . . ” includes “acryl . . . ,” “methacryl . . . ,” or mixtures thereof.

As used herein, “molecular weight” refers to number-average molecular weight as measured by ¹H NMR spectroscopy, unless clearly indicated otherwise.

Disclosed herein are methods of patterning substates. For examples, disclosed herein are methods comprising irradiating a portion of a top surface of a substrate with a laser. In some examples, the methods further comprise cleaning and/or etching the substrate prior to irradiation.

The laser can have any suitable fluence. For example, the laser have a fluence of 0.05 J/cm² or more (e.g., 0.06 J/cm² or more, 0.07 J/cm² or more, 0.08 J/cm² or more, 0.09 J/cm² or more, 0.1 J/cm² or more, 0.15 J/cm² or more, 0.2 J/cm² or more, 0.25 J/cm² or more, 0.3 J/cm² or more, 0.35 J/cm² or more, 0.4 J/cm² or more, 0.45 J/cm² or more, 0.5 J/cm² or more, 0.6 J/cm² or more, 0.7 J/cm² or more, 0.8 J/cm² or more, 0.9 J/cm² or more, 1 J/cm² or more, 1.25 J/cm² or more, 1.5 J/cm² or more, 1.75 J/cm² or more, 2 J/cm² or more, or 2.25 J/cm² or more). In some examples, the laser can have a fluence of 2.5 J/cm² or less (e.g., 2.25 J/cm² or less, 2 J/cm² or less, 1.75 J/cm² or less, 1.5 J/cm² or less, 1.25 J/cm² or less, 1 J/cm² or less, 0.9 J/cm² or less, 0.8 J/cm² or less, 0.7 J/cm² or less, 0.6 J/cm² or less, 0.5 J/cm² or less, 0.45 J/cm² or less, 0.4 J/cm² or less, 0.35 J/cm² or less, 0.3 J/cm² or less, 0.25 J/cm² or less, 0.2 J/cm² or less, 0.15 J/cm² or less, 0.1 J/cm² or less, 0.09 J/cm² or less, 0.08 J/cm² or less, 0.07 J/cm² or less, or 0.06 J/cm² or less). The laser fluence can range from any of the minimum values described above from any of the maximum values described above. For example, the laser can have a fluence of from 0.05 to 2.5 J/cm² (e.g., from 0.05 to 1.25 J/cm², from 1.25 to 2.5 J/cm², from 0.05 to 0.5 J/cm², from 0.5 to 1 J/cm², from 1 to 1.5 J/cm², from 1.5 to 2 J/cm², from 2 to 2.5 J/cm², from 0.05 to 2 J/cm², from 0.05 to 1.5 J/cm², from 0.05 to 1 J/cm², from 0.05 to 0.25 J/cm², from 0.1 to 2.5 J/cm², from 0.25 to 2.5 J/cm², from 0.5 to 2.5 J/cm², from 1 to 2.5 J/cm², from 1.5 to 2.5 J/cm², from 0.1 to 2 J/cm², from 0.1 to 1.5 J/cm², from 0.1 to 1 J/cm², from 0.25 to 0.7 J/cm², or from 0.5 to 0.7 J/cm²). In some examples, the laser fluence can be selected in view of the threshold of intrinsic laser damage and/or the substrate.

The laser can have any suitable wavelength. For example, the laser can have a wavelength of 190 nanometers (nm) or more (e.g., 200 nm or more, 225 nm or more, 250 nm or more, 275 nm or more, 300 nm or more, 325 nm or more, 350 nm or more, 375 nm or more, 400 nm or more, 425 nm or more, 450 nm or more, 475 nm or more, 500 nm or more, 550 nm or more, 600 nm or more, 650 nm or more, 700 nm or more, 750 nm or more, 800 nm or more, 850 nm or more, 900 nm or more, 950 nm or more, 1000 nm or more, 1100 nm or more, 1200 nm or more, 1300 nm or more, 1400 nm or more, 1500 nm or more, 1600 nm or more, 1700 nm or more, 1800 nm or more, 1900 nm or more, 2000 nm or more, 2100 nm or more, 2200 nm or more, 2300 nm or more, or 2400 nm or more). In some examples, the laser can have a wavelength of 2500 nm or less (e.g., 2400 nm or less, 2300 nm or less, 2200 nm or less, 2100 nm or less, 2000 nm or less, 1900 nm or less, 1800 nm or less, 1700 nm or less, 1600 nm or less, 1500 nm or less, 1400 nm or less, 1300 nm or less, 1200 nm or less, 1100 nm or less, 1000 nm or less, 950 nm or less, 900 nm or less, 850 nm or less, 800 nm or less, 750 nm or less, 700 nm or less, 650 nm or less, 600 nm or less, 550 nm or less, 500 nm or less, 475 nm or less, 450 nm or less, 425 nm or less, 400 nm or less, 375 nm or less, 350 nm or less, 325 nm or less, 300 nm or less, 275 nm or less, 250 nm or less, or 225 nm or less). The wavelength of the laser can range from any of the minimum values described above to any of the maximum values described above. For example, the laser can have a wavelength of from 190 nm to 2500 nm (e.g., from 190 nm to 1400 nm, from 1400 nm to 2500 nm, from 190 nm to 500 nm, from 500 nm to 1000 nm, from 1000 nm to 1500 nm, from 1500 nm to 2000 nm, from 2000 nm to 2500 nm, from 190 nm to 2000 nm, from 190 nm to 1500 nm, from 190 nm to 1000 nm, from 190 nm to 750 nm, from 190 nm to 400 nm, from 200 nm to 2500 nm, from 250 nm to 2000 nm, from 500 nm to 2000 nm, from 750 nm to 2000 nm, from 1000 nm to 2000 nm, from 200 nm to 2400 nm, from 225 nm to 2000 nm, from 250 nm to 1000 nm, from 250 nm to 750 nm, 250 nm to 500 nm, from 300 nm to 400 nm, or from 325 to 375 nm).

In some examples, the laser can have a fluence of from 0.05 to 2.5 J/cm² and a wavelength of from 190 nm to 2500 nm. In some examples, the laser can have a fluence of from 0.5 to 0.7 J/cm² and a wavelength of from 250 nm to 500 nm, such as a wavelength from 325 to 375 nm.

In some examples, the irradiation comprises a laser pulse. The pulse can have any suitable duration. For example, the pulse can have a duration of 200 femtoseconds or more (e.g., 250 femtoseconds or more, 300 femtoseconds or more, 350 femtoseconds or more, 400 femtoseconds or more, 450 femtoseconds or more, 500 femtoseconds or more, 600 femtoseconds or more, 700 femtoseconds or more, 800 femtoseconds or more, 900 femtoseconds or more, 1 picosecond or more, 1.25 picoseconds or more, 1.5 picoseconds or more, 1.75 picoseconds or more, 2 picoseconds or more, 2.5 picoseconds or more, 3 picoseconds or more, 3.5 picoseconds or more, 4 picoseconds or more, 4.5 picoseconds or more, 5 picoseconds or more, 6 picoseconds or more, 7 picoseconds or more, 8 picoseconds or more, 9 picoseconds or more, 10 picoseconds or more, 15 picoseconds or more, 20 picoseconds or more, 25 picoseconds or more, 30 picoseconds or more, 35 picoseconds or more, 40 picoseconds or more, 45 picoseconds or more, 50 picoseconds or more, 60 picoseconds or more, 70 picoseconds or more, 80 picoseconds or more, 90 picoseconds or more, 100 picoseconds or more, 125 picoseconds or more, 150 picoseconds or more, 175 picoseconds or more, 200 picoseconds or more, 250 picoseconds or more, 300 picoseconds or more, 350 picoseconds or more, 400 picoseconds or more, 450 picoseconds or more, 500 picoseconds or more, 600 picoseconds or more, 700 picoseconds or more, 800 picoseconds or more, 900 picoseconds or more, 1 nanosecond or more, 1.25 nanoseconds or more, 1.5 nanoseconds or more, 1.75 nanoseconds or more, 2 nanoseconds or more, 2.5 nanoseconds or more, 3 nanoseconds or more, 3.5 nanoseconds or more, 4 nanoseconds or more, 4.5 nanoseconds or more, 5 nanoseconds or more, 6 nanoseconds or more, 7 nanoseconds or more, 8 nanoseconds or more, or 9 nanoseconds or more). In some examples, the pulse can have a duration of 10 nanoseconds or less (e.g., 9 nanoseconds or less, 8 nanoseconds or less, 7 nanoseconds or less, 6 nanoseconds or less, 5 nanoseconds or less, 4.5 nanoseconds or less, 4 nanoseconds or less, 3.5 nanoseconds or less, 3 nanoseconds or less, 2.5 nanoseconds or less, 2 nanoseconds or less, 1.75 nanoseconds or less, 1.5 nanoseconds or less, 1.25 nanoseconds or less, 1 nanosecond or less, 900 picoseconds or less, 800 picoseconds or less, 700 picoseconds or less, 600 picoseconds or less, 500 picoseconds or less, 450 picoseconds or less, 400 picoseconds or less, 350 picoseconds or less, 300 picoseconds or less, 250 picoseconds or less, 200 picoseconds or less, 175 picoseconds or less, 150 picoseconds or less, 125 picoseconds or less, 100 picoseconds or less, 90 picoseconds or less, 80 picoseconds or less, 70 picoseconds or less, 60 picoseconds or less, 50 picoseconds or less, 45 picoseconds or less, 40 picoseconds or less, 35 picoseconds or less, 30 picoseconds or less, 25 picoseconds or less, 20 picoseconds or less, 15 picoseconds or less, 10 picoseconds or less, 9 picoseconds or less, 8 picoseconds or less, 7 picoseconds or less, 6 picoseconds or less, 5 picoseconds or less, 4.5 picoseconds or less, 4 picoseconds or less, 3.5 picoseconds or less, 3 picoseconds or less, 2.5 picoseconds or less, 2 picoseconds or less, 1.75 picoseconds or less, 1.5 picoseconds or less, 1.25 picoseconds or less, 1 picosecond or less, 900 femtoseconds or less, 800 femtoseconds or less, 700 femtoseconds or less, 600 femtoseconds or less, 500 femtoseconds or less, 450 femtoseconds or less, 400 femtoseconds or less, 350 femtoseconds or less, 300 femtoseconds or less, or 250 femtoseconds or less). The duration of the pulse can range from any of the minimum values described above to any of the maximum values described above. For example, the pulse can have a duration of from 200 femtoseconds to 10 nanoseconds (e.g., from 200 femtoseconds to 1 picosecond, from 1 picosecond to 1 nanosecond, from 1 nanosecond to 10 nanoseconds, from 200 femtoseconds to 1 nanosecond, from 200 femtoseconds to 500 picoseconds, from 200 femtoseconds to 900 femtoseconds, from 500 femtoseconds to 10 nanoseconds, from 1 picosecond to 10 nanoseconds, from 500 picoseconds to 10 nanoseconds, from 250 femtoseconds to 9 nanoseconds, or from 500 femtoseconds to 8 nanoseconds). In some examples, the pulse can have a duration of from 1 nanosecond to 10 nanoseconds (e.g., from 2 ns to 8 ns, from 3 ns to 7 ns, or from 4 ns to 6 ns).

In some examples, the laser can have a fluence of from 0.05 to 2.5 J/cm² and the pulse can have a duration of from 200 femtoseconds to 10 nanoseconds. In some examples, the laser can have a wavelength of from 190 nm to 2500 nm and the pulse can have a duration of from 200 femtoseconds to 10 nanoseconds. In some examples, the laser can have a fluence of from 0.05 to 2.5 J/cm² and a wavelength of from 190 nm to 2500 nm and the pulse can have a duration of from 200 femtoseconds to 10 nanoseconds.

In some examples, the laser can have a fluence of from 0.5 to 0.7 J/cm² and the pulse can have a duration of from 1 to 10 nanoseconds. In some examples, the laser can have a wavelength of from 250 nm to 500 nm, such as a wavelength from 325 to 375 nm, and the pulse can have a duration of from 1 to 10 nanoseconds. In some examples, the laser can have a fluence of from 0.5 to 0.7 J/cm² and a wavelength of from 250 nm to 500 nm, such as a wavelength from 325 to 375 nm, and the pulse can have a duration of from 1 to 10 nanoseconds.

In some examples, the irradiation has an absorption depth of 1 nanometer (nm) or more (e.g., 1.5 nm or more, 2 nm or more, 2.5 nm or more, 3 nm or more, 3.5 nm or more, 4 nm or more, 4.5 nm or more, 5 nm or more, 5.5 nm or more, 6 nm or more, 6.5 nm or more, 7 nm or more, 7.5 nm or more, 8 nm or more, 8.5 nm or more, or 9 nm or more). In some examples, the irradiation has an absorption depth of 10 nm or less (e.g., 9.5 nm or less, 9 nm or less, 8.5 nm or less, 8 nm or less, 7.5 nm or less, 7 nm or less, 6.5 nm or less, 6 nm or less, 5.5 nm or less, 5 nm or less, 4.5 nm or less, 4 nm or less, 3.5 nm or less, 3 nm or less, 2.5 nm or less, or 2 nm or less). The absorption depth of the irradiation can range from any of the minimum values described above to any of the maximum values described above. For example, the irradiation can have an absorption depth of from 1 nm to 10 nm (e.g., from 1 nm to 5 nm, from 5 nm to 10 nm, from 1 nm to 4 nm, from 4 nm to 7 nm, from 7 nm to 10 nm, from 1 nm to 9 nm, from 1 nm to 8 nm, from 1 nm to 7 nm, from 1 nm to 6 nm, from 1 nm to 3 nm, from 2 nm to 10 nm, from 3 nm to 10 nm, from 4 nm to 10 nm, from 6 nm to 10 nm, from 8 nm to 10 nm, from 1.5 nm to 9.5 nm, or from 2 nm to 8 nm).

In some examples, the laser parameters can be selected such that the irradiation is below the laser-induced damage threshold.

In some examples, the irradiated portion is oxidized by the laser.

In some examples, the portion irradiated with the laser defines a growth surface and the remaining portion (e.g., the non-irradiated portion) comprises a non-growth surface or wherein the portion irradiated with the laser defines a non-growth surface and the remaining portion (e.g., the non-irradiated portion) comprises a growth surface; and the method further comprises subsequently depositing a first material on the substrate, wherein the first material selectively deposits on the growth surface relative to the non-growth surface, thereby forming a patterned substrate.

In some examples, the methods further comprise irradiating a portion of the patterned substrate with the laser; wherein the portion irradiated with the laser defines a growth surface and the remaining portion (e.g., the non-irradiated portion) comprises a non-growth surface, or wherein the portion irradiated with the laser defines a non-growth surface and the remaining portion (e.g., the non-irradiated portion) comprises a growth surface; and subsequently depositing a second material on the substrate, wherein the second material selectively deposits on the growth surface relative to the non-growth surface. The irradiation can be the same as or different than the initial irradiation.

In some examples, the irradiated portion of the patterned substrate comprises the top surface of the substrate. In some examples, the irradiated portion of the patterned substrate comprises the first material. In some examples, the irradiated portion is oxidized by the laser.

In some examples, the non-growth surface is substantially free of the first material and/or the second material.

In some examples, the first material and the second material are the same. In some examples, the first material and the second material are different.

The first material and the second material can independently comprise any suitable material. In some examples, the first material and/or the second material comprises a metal, an oxide such as a metal oxide, an organic resist, a semiconductor, or a combination thereof. In some examples, the organic resist comprises a polymeric resist, such as a photoresist and/or a non-imprint resist. In some examples, the organic resist comprises an atomic, molecular, or self-assembled monolayer resist. In some examples, the organic resist comprises an atomic or molecular resist.

The first material and/or the second material can be deposited using any suitable method. In some examples, depositing the first material and/or the second material comprises chemical vapor deposition (CVD), atomic layer deposition (ALD), physical vapor deposition (PVD), atomic layer etching (ALE), or a combination thereof. In some examples, depositing the first material and/or the second material comprises chemical vapor deposition (CVD), atomic layer deposition (ALD), or a combination thereof.

The method can be performed at any suitable temperature. For example, the method can be performed at a temperature of 0° C. or more (e.g., 5° C. or more, 10° C. or more, 15° C. or more, 20° C. or more, 25° C. or more, 30° C. or more, 35° C. or more, 40° C. or more, 45° C. or more, 50° C. or more, 60° C. or more, 70° C. or more, 80° C. or more, 90° C. or more, 100° C. or more, 125° C. or more, 150° C. or more, 175° C. or more, 200° C. or more, 225° C. or more, 250° C. or more, 275° C. or more, 300° C. or more, 325° C. or more, 350° C. or more, or 375° C. or more). In some examples, the method can be performed at a temperature of 400° C. or less (e.g., 375° C. or less, 350° C. or less, 325° C. or less, 300° C. or less, 275° C. or less, 250° C. or less, 225° C. or less, 200° C. or less, 175° C. or less, 150° C. or less, 125° C. or less, 100° C. or less, 90° C. or less, 80° C. or less, 70° C. or less, 60° C. or less, 50° C. or less, 45° C. or less, 40° C. or less, 35° C. or less, 30° C. or less, 25° C. or less, 20° C. or less, 15° C. or less, or 10° C. or less). The temperature at which the method is performed can range from any of the minimum values described above to any of the maximum values described above. For example, the method can be performed at a temperature of from 0-400° C. (e.g., from 0° C. to 200° C., from 200° C. to 400° C., from 0° C. to 100° C., from 100° C. to 200° C., from 200° C. to 300° C., from 300° C. to 400° C., from 0° C. to 300° C., from 0° C. to 50° C., from 0° C. to 25° C., from 10° C. to 400° C., from 25° C. to 400° C., from 50° C. to 400° C., from 100° C. to 400° C., from 5° C. to 375° C., from 10° C. to 350° C., or from 10° C. to 50° C.). In some examples, the method is performed at room temperature. As used herein, room temperature means at a temperature of from 20° C. to 25° C.

The substrate can have any suitable temperature during the method. For example, the substrate can have a temperature of from 0° C. or more (e.g., 5° C. or more, 10° C. or more, 15° C. or more, 20° C. or more, 25° C. or more, 30° C. or more, 35° C. or more, 40° C. or more, 45° C. or more, 50° C. or more, 60° C. or more, 70° C. or more, 80° C. or more, 90° C. or more, 100° C. or more, 125° C. or more, 150° C. or more, 175° C. or more, 200° C. or more, 225° C. or more, 250° C. or more, 275° C. or more, 300° C. or more, 325° C. or more, 350° C. or more, or 375° C. or more). In some examples, the substrate can have a temperature of 400° C. or less (e.g., 375° C. or less, 350° C. or less, 325° C. or less, 300° C. or less, 275° C. or less, 250° C. or less, 225° C. or less, 200° C. or less, 175° C. or less, 150° C. or less, 125° C. or less, 100° C. or less, 90° C. or less, 80° C. or less, 70° C. or less, 60° C. or less, 50° C. or less, 45° C. or less, 40° C. or less, 35° C. or less, 30° C. or less, 25° C. or less, 20° C. or less, 15° C. or less, or 10° C. or less). The temperature of the substrate can range from any of the minimum values described above to any of the maximum values described above. For example, the substrate can have a temperature of from 0-400° C. (e.g., from 0° C. to 200° C., from 200° C. to 400° C., from 0° C. to 100° C., from 100° C. to 200° C., from 200° C. to 300° C., from 300° C. to 400° C., from 0° C. to 300° C., from 0° C. to 50° C., from 0° C. to 25° C., from 10° C. to 400° C., from 25° C. to 400° C., from 50° C. to 400° C., from 100° C. to 400° C., from 5° C. to 375° C., from 10° C. to 350° C., or from 10° C. to 50° C.). In some examples, the substrate is at room temperature. In some examples, the temperature of the substrate is not substantially changed by the irradiation (e.g., the irradiation does not substantially heat the substrate).

The method can be performed under any suitable atmosphere and/or pressure. In some examples, the methods can be performed in ambient atmosphere, an oxygen enriched atmosphere, an inert atmosphere (e.g., nitrogen, argon, etc.).

In some examples, the method is performed under vacuum, such as low, medium, high, or ultra-high vacuum.

In some examples, the method is performed at a pressure of 1×10⁻⁷ Pascals (Pa) or more (e.g., 5×10⁻⁷ Pa or more, 1×10⁻⁶ Pa or more, 5×10⁻⁶ Pa or more, 1×10⁻⁵ Pa or more, 5×10⁻⁵ Pa or more, 1×10⁻⁴ Pa or more, 5×10⁻⁴ Pa or more, 1×10⁻³ Pa or more, 5×10⁻³ Pa or more, 1×10⁻² Pa or more, 5×10⁻² Pa or more, 1×10⁻¹ Pa or more, 5×10⁻¹ Pa or more, 1 Pa or more, 5 Pa or more, 10 Pa or more, 50 or Pa or more, or 100 Pa or more). In some examples, the method is performed at a pressure of 500 Pa or less (e.g., 100 Pa or less, 50 Pa or less, 10 Pa or less, 5 Pa or less, 1 Pa or less, 5×10⁻¹ Pa or less, 1×10⁻¹ Pa or less, 5×10⁻² Pa or less, 1×10⁻² Pa or less, 5×10⁻³ Pa or less, 1×10⁻³ Pa or less, 5×10⁻⁴ Pa or less, 1×10⁻⁴ Pa or less, 5×10⁻⁵ Pa or less, 1×10⁻⁵ Pa or less, 5×10⁻⁶ Pa or less, 1×10⁻⁶ Pa or less, or 5×10⁻⁷ Pa or less). The pressure at which the method is performed can range from any of the minimum values described above to any of the maximum values described above. For example, the method can be performed at a pressure of from 1×10⁻⁷ Pascals (Pa) to 500 Pa (e.g., from 1×10⁻⁷ Pa to 1×10⁻² Pa, from 1×10⁻² Pa to 500 Pa, from 1×10⁻⁷ to 100 Pa, from 1×10⁻⁷ to 10 Pa, from 1×10⁻⁷ to 1 Pa, from 1×10⁻⁷ Pa to 0.1 Pa, 1×10⁻⁷ Pa to 1×10⁻³ Pa, or from 1×10⁻⁷ Pa to 1×10⁻⁵ Pa).

In some examples, the method is performed at a temperature of from 0 to 400° C. and a pressure of from 1×10⁻⁷ Pascals (Pa) to 500 Pa. In some examples, the method is performed at room temperature and under vacuum.

The substrate can comprise any suitable substrate. Examples of suitable substrates include, but are not limited to, inorganic semiconductors, insulators and conductors. In some examples, the substrate can comprise Group 3, 4, 5 semiconductors, oxides, nitrides and oxynitrides, including doped materials.

In some examples, the substrate comprises Si, Ge, In, Sn, Al, Ti, or a combination thereof. In some examples, the substrate comprises silicon. In some examples, the substrate comprises Si(100), Si(110), Si(111), or Si(110).

In some examples, the substrate comprises Si(100). In some examples, the top surface of the substrate comprises H—Si(100). In some examples, the irradiated portion of the top surface of the substrate is oxidized by the laser. In some examples, the irradiated portion of the top surface of the substrate comprises OH—Si(100).

In some examples, the methods further comprise wet chlorination of the substrate before or after irradiation, but before deposition and after cleaning/etching. In some examples, the top surface of the substrate comprises Cl—Si(100). In some examples, the irradiated portion of the top surface of the substrate comprises ClₓO_{y}—Si(100).

In some examples, the method comprises area-selective atomic layer deposition, atomic layer etching, scanning tunneling microscopy (STM), extreme UV lithography, or a combination thereof.

Also disclosed herein are patterned substrates made by any of the methods disclosed herein. Also disclosed herein are articles of manufacture made by any of the methods disclosed herein. Also disclosed herein are articles of manufacture include any of the patterned substrates made by any of the methods disclosed herein. The article of manufacture can, for example, comprise an electronic device, a photonic device, an optical device, an optoelectronic device, or a combination thereof.

The examples below are intended to further illustrate certain aspects of the methods, devices, and compositions described herein, and are not intended to limit the scope of the claims.

### EXAMPLES

The following examples are set forth below to illustrate the methods and results according to the disclosed subject matter. These examples are not intended to be inclusive of all aspects of the subject matter disclosed herein, but rather to illustrate representative methods, compositions, and results. These examples are not intended to exclude equivalents and variations of the present invention, which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in ° C. or is at ambient temperature, and pressure is at or near atmospheric. There are numerous variations and combinations of reaction conditions, e.g., component concentrations, temperatures, pressures, and other reaction ranges and conditions that can be used to optimize the product purity and yield obtained from the described process. Only reasonable and routine experimentation will be required to optimize such process conditions.

### Example 1

Described herein are methods of patterning atomic and molecular resists using pulsed-laser radiation for Area-Selective Atomic Layer Deposition (AS ALD).

Provided herein is methodology for universal patterning of atomic and molecular ALD resists using pulsed laser radiation. This can lead to the development of continuous and energy-efficient manufacturing platform for bottom-up deposition and high-resolution patterning of opto-electronic device components.

Overview. A goal of this work is to develop an energy-efficient manufacturing platform for bottom-up deposition and patterning of opto-electronic device components based on an approach to pattern the substrate materials using pulsed laser radiation and atomic and mono-molecular ALD resists.

The total consumption of electricity by opto-electronic devices is predicted to surpass the global energy production by 2050 unless radical changes are made in the efficiency, design, and manufacturing of the device components. The ever-increasing number of the transistors and their continuous miniaturization requires progressively denser microchips that are less efficient, require more power, and face issues associated with thermal management. This trend can be avoided by inventing new manufacturing techniques that open access to new and highly efficient 3D chip designs rather than by relaying on unsustainable scaling. With the future of microelectronics moving beyond Moore's Law, atomically precise manufacturing is becoming a bottleneck in achieving the required degree of device precision. The future generation of atomically precise and ultra-efficient opto-electronic and quantum devices will rely on 3D architectures that are only accessible via bottom-up processes, such as area-selective atomic layer deposition (AS-ALD) and atomic layer etching (ALE).

Another issue in opto-electronic device manufacturing is that the electricity consumption by the devices does not account for the energy required to manufacture them. Current top-down micromachining relies on extremely material- and energy-intensive manufacturing. Considering a typical 3-5-year lifespan of an opto-electronic gadget, the energy required to manufacture it is considerably higher than the energy used during its operation. The inherent nature of top-down fabrication necessitates that most of the materials used to build the device are wasted and/or need to be recycled or purified (photoresists, developers, resist removers, etched semiconducting materials). Moreover, such fundamental top-down techniques as photolithography and plasma-based reactive ion etching require massive amounts of energy, most of which has to be absorbed as heat by advanced cooling systems. None of the material deposition, removing or patterning steps in top-down manufacturing take advantage of chemical processes with favorable thermodynamic profiles that can dramatically reduce energy requirements or rely on molecular/atomic-scale self-aligned phenomena that can achieve high resolution in both lateral and vertical dimensions. In contrast, AS-ALD/ALE build and assemble device components in an additive manner via atomically precise and self-aligned positioning of the device components, and they rely on efficient self-limiting chemical reactions that are driven to completion via favorable thermodynamics and kinetics.

One of the major challenges of such bottom-up manufacturing that preclude widespread AS-ALD/ALE implementation is the lack of unifying conditions and patterning methods that are universally compatible with different materials and device architectures. In the past, researchers have developed several substrate-specific AS-ALD resist masks and patterning methods, but none of them are compatible with a variety of substrate materials. Currently, there is a need in developing new universal ALD resist deposition, regeneration and patterning methods that do not require major substrate optimization. Another challenge of AS-ALD/ALE fabrication is the reliance on processing steps that are incompatible with vacuum-based deposition or etching.

The work described herein investigates universal patterning of atomic and mono-molecular ALD resists for area-selective atomic layer deposition. A goal of this project is to integrate atomic and mono-molecular ALD resist materials with universal photo-initiated resist patterning into an in-situ manufacturing process that is compatible with a variety of substrates and ALD chemistries without significant optimization.

Current state of technology. Area-selective atomic layer deposition (AS-ALD) relies on the patterns of growth and non-growth surfaces (GS and NGS), which promote (growth surface) and block (non-growth surface) sequential ALD reactions [1-4]. The growth selectivity is typically achieved by either directly exploiting the differences in surface properties of the heterogeneous growth surface-non-growth surface materials or by patterning ALD resists that block deposition on the homogeneous growth-promoting interfaces. In both cases, the growth selectivity diminishes over time when the growth rates on growth surface and non-growth surface become comparable. The selectivity window can be extended either by selecting resists with longer growth delays or by periodically regenerating resists after several ALD cycles.

Typical AS-ALD resists include polymeric [5-9] and inorganic [10-14]thin films. They are often deposited via traditional stencil lithography or photolithography, negating the potential high-resolution advantages of the AS-ALD. Thick resist layers also contribute to non-homogeneous growth profiles in the growth surface areas [15] and require additional etching steps to remove excess material. Such resist deposition/patterning methods are difficult to interface with the ALD process and to implement for in-situ film growth.

Considering the limitations of the thin film resists, recent efforts in AS-ALD were directed toward the development of small molecule and atomic resists that can potentially achieve sub-nm resolution. However, the small molecule and atomic resist examples reported to date rely on slow and expensive patterning methods such as scanning tunneling microscopy or on low-resolution printing techniques. These methods are also highly specific to particular resist-substrate combinations.

It is hypothesized that light-substrate interactions can introduce growth promoting defects on any small molecule or atomic ALD resists enabling universal, in-situ patterning of a various substrate/resist combinations. Initial results show that pulsed laser exposures of the monoatomic resist layers can promote chemical oxidation of the resist molecules without causing physical substrate damage. Such oxidized areas were shown to promote ALD growth of Al₂O₃ on otherwise ALD blocking resist layer.

Research and methodology. In this work, patterning of the small molecule and atomic resists using pulsed laser oxidation is investigated. Typically, patterning with small molecules utilizes various renditions of microcontact printing [16, 17], which limits the resolution of the printed features to a micrometer range due to the molecular diffusion. In the past, a diffusion-less method for patterning organic molecules with sub-50 nm resolution was developed, but this technique remains specific to only certain functional groups [18-20].

Potentially, pulsed laser patterning can achieve the same resolution as the current state-of the-art photolithographic processing. In addition, by controlling the wavelength and the duration of the pulse, the laser patterning conditions can be translated to other higher resolution methods (STM or extreme UV lithography) by modeling photo-energy distribution and dissipation within the material both in time and space. Scanning laser exposure is scalable to conventional wafer-size substrates, and it can potentially be implemented during the ALD cycles for bulk cleaning of the non-growth areas before the resist regeneration. Most importantly, pulsed laser patterning provides an efficient way to deliver energy into a specific chemical transformation without dissipating it as heat into the bulk of the substrate. For example, by adjusting the pulse length and the wavelength, the absorption depth of the laser radiation can be limited to the top 3-5 nm of the substrate material (e.g., 5 ns pulse, 355 nm on silicon) where most of it can be harnessed to enable a chemical transformation.

This initial study focuses on the following tasks related to growth-promoting defects generation:

Determining laser-exposure conditions and defect initiation mechanism: Initial experiments explore varying laser parameters to gain a finer control and understanding over the laser energy transfer to the resist and substrate surface. The parameters investigated are the laser pulse duration, pulse intensity and wavelength. Depending on these parameters, certain surface interactions such as photoinduced reactions, bond dissociation and/or thermal-based diffusion or phase-transition can be enabled. Thus, it can be important to select conditions which effectively pattern the ALD resists without initiating diffusion, annealing, or crystallographic damage to the substrate (e.g., exposures below the laser-induced damage threshold (LIDT)).

Determining the Defect density vs. ALD selectivity: Subsequently, how the density of the photo-generated defects affects selectivity of the exposed resist molecules can be explored. A goal will be to determine the minimum defect density that achieves the maximum difference in selectivity between the exposed and unexposed resist areas. The defect density can be controlled by repeating pulsed laser exposures below the laser-induced damage threshold values.

Self-aligned ALD growth resolution: Initial results show that the laser-exposed area (355 nm, 5 ns pulse) on Si—Cl substrate has very sharp edge resolution. It is hypothesized that this is because the pulsed laser energy was delivered directly into the top 5 nm of the substrate material (by adjusting the wavelength and pulse length) and was utilized to promote Si—Cl oxidation before dissipating as heat into the bulk. In further work, how the resolution of the self-aligned ALD patterns changes as a function of the initial resist selectivity and selectivity window and the number of ALD cycles can be investigated.

Potential impact to semiconductor manufacturing. Potentially, scanned pulsed laser exposures can be directly applied to pattern small molecule and atomic resist layers in-situ during the ALD processing. The pulsed laser patterning conditions can also be translated to other high-resolution patterning methods via modeling. For example, by calculating the adsorption depth of the pulsed laser radiation on different substrates from the laser exposure parameters, by measuring the total amount of energy delivered into the laser exposed areas, and by establishing a mechanism of the laser-induced defect formation (thermal photo-oxidation vs. direct bond dissociation), parameters for patterning ALD resists using ultra-high-resolution methods, such as extreme UV lithography (EUV) and scanning tunneling microscopy (STM), can be selected. Both EUV and STM can induce chemical reactions or directly dissociate molecular bonds depending on the surrounding environment and exposure dose or tunneling current density. The laser exposure experiments can yield estimated exposure parameters for these methods that can be subsequently validated in industry.

### REFERENCES

1. Parsons G N et al. Area-Selective Deposition: Fundamentals, Applications, and Future Outlook. Chemistry of Materials 2020, 32 (12), 4920-4953.
2. George S M. Atomic Layer Deposition: An Overview. Chemical Reviews 2010, 110 (1), 111-131.
3. Mackus A J M et al. From the Bottom-Up: Toward Area-Selective Atomic Layer Deposition with High Selectivity. Chemistry of Materials 2019, 31 (1), 2-12.
4. Lee H B R et al. Nanopatterning by Area-Selective Atomic Layer Deposition. 2012; pp 193-225.
5. Cho T H et al. Area-Selective Atomic Layer Deposition Patterned by Electrohydrodynamic Jet Printing for Additive Manufacturing of Functional Materials and Devices. ACS Nano 2020, 14 (12), 17262-17272.
6. Deminskyi P et al. Area-selective atomic layer deposition of noble metals: Polymerized fluorocarbon layers as effective growth inhibitors. Journal of Vacuum Science & Technology A 2020, ASD2020 (1), 022402.
7. Krishtab M et al. Cyclic Plasma Halogenation of Amorphous Carbon for Defect-Free Area-Selective Atomic Layer Deposition of Titanium Oxide. ACS Applied Materials & Interfaces 2021, 13 (27), 32381-32392.
8. Miyajima C et al. Selective dry etching of U V-nanoimprinted resin passivation masks for area selective atomic layer deposition of aluminum oxide. Journal of Vacuum Science & Technology B 2021, 39 (5), 052804.
9. Papananou H et al. Dopamine-Mediated Polymer Coating Facilitates Area-Selective Atomic Layer Deposition. ACS Applied Polymer Materials 2021, 3 (10), 4924-4931.
10. Chou C Y et al. Atomic Layer Nucleation Engineering: Inhibitor-Free Area-Selective Atomic Layer Deposition of Oxide and Nitride. Chemistry of Materials 2021, 33 (14), 5584-5590.
11. Gasvoda R J et al. Selective Gas-Phase Functionalization of SiO₂ and SiNₓ Surfaces with Hydrocarbons. Langmuir 2021, 37 (13), 3960-3969.
12. Kim H M et al. Area-Selective Atomic Layer Deposition of Ruthenium Using a Novel Ru Precursor and H₂O as a Reactant. Chemistry of Materials 2021, 33 (12), 4353-4361.
13. Lee J et al. Inherently Area-Selective Atomic Layer Deposition of SiO₂ Thin Films to Confer Oxide Versus Nitride Selectivity. Advanced Functional Materials 2021, 31 (33), 2102556.
14. Yi-Cheng L et al. Inherently Area-Selective Atomic Layer Deposition of Manganese Oxide through Electronegativity-Induced Adsorption. Molecules 2021, 26 (10), 3056.
15. Klement P et al. Surface Diffusion Control Enables Tailored-Aspect-Ratio Nanostructures in Area-Selective Atomic Layer Deposition. ACS Applied Materials & Interfaces 2021, 13 (16), 19398-19405.
16. Tien J et al. Microcontact printing of SAMs. Thin Films (San Diego) 1998, 24, 227-254.
17. Wendeln C et al. Microcontact printing. Structuring and modification of surfaces. GIT Labor-Fachz. 2013, 57 (2), 114-116.
18. Shestopalov A A et al. Inkless Microcontact Printing on Self-Assembled Monolayers of Fmoc-Protected Aminothiols. J. Am. Chem. Soc. 2007, 129 (45), 13818-13819.
19. Shestopalov A A et al. Inkless Microcontact Printing on SAMs of Boc- and TBS-Protected Thiols. Nano Lett. 2010, 10 (1), 43-46.
20. Shestopalov A A et al. Catalytic Microcontact Printing on Chemically Functionalized H-Terminated Silicon. Langmuir 2010, 26 (3), 1449-1451.

### Example 2—Laser-Assisted Oxidation of H—Si(100)

Abstract: Here a technique is described to increase the rate of oxidation on hydrogen-terminated Si(100) using Nd:YAG laser-assisted oxidation (LAO) under low vacuum and at room temperature. It has been established that there exists an interval of laser beam energy density (0.25-0.70 J/cm²) in which the rate of surface oxidation is enhanced under low vacuum, without initiating surface melting. The oxidation process appears to be controlled by the laser beam energy density rather than the number of pulses and the higher laser power results in a higher surface oxide content. X-ray photoelectron spectroscopy (XPS) was used to provide information on the type and amount of surface oxide that is generated as a function of laser fluence. Scanning electron microscopy (SEM) was used to image exposure sites and paired with laser beam profiles to determine the general locality of the oxidizing effect. Atomic force microscopy (AFM) was used to verify that the underlying surface morphology was not physically altered by laser exposure. Spectroscopic ellipsometry (SE) was used to measure oxide thickness within and outside irradiated surface sites. From these results it was concluded that patterned oxide generation on Si(100) formed in mild vacuum by the technique of Nd:YAG laser-assisted oxidation at low temperature is a potentially useful substrate processing technique for many device applications.

Background: The oxidation of silicon is an important topic in the modern fabrication of nanoelectromechanical systems (NEMS), microelectromechanical systems (MEMS), and even biomaterial systems [A1, A2]. Thus, there is great interest in processing techniques that can improve the existing methods for generating substrates with surface SiO₂ for a myriad of applications. Current techniques for the oxidation of Si surfaces mostly focus on generating a continuous thin film of SiO₂ and are often characterized by high processing temperatures. Therefore, it has long been thought desirable to find a technique which (1) induces localized oxidation of silicon with good spatial resolution, (2) is carried out at lower processing temperatures, and which (3) does not introduce crystallographic damage to the surface. To achieve more precise control of the oxidation process it is necessary to first decrease the growth temperature. However, by doing so the oxidation process becomes exponentially slower [A2]. To enhance the Si-oxidation process at low temperatures various growth techniques have been employed, such as plasma, ion-beam, visible, and ultraviolet (UV) radiation [A3]. Of these techniques, SiO₂ generation by UV radiation via a continuous or pulsed light source seems particularly promising in achieving these objectives. Specifically, pulsed UV laser-assisted oxidation (LAO) of silicon has gained some research interest in the past for its ability to achieve good control over the thickness of very thin oxide layers, on the scale of 1-2 nm, at low processing temperatures [A4, A5]. Drawing from this, reported herein are findings using a 355 nm Nd:YAG laser system which gesture towards a vacuum-based laser-assisted oxidation technique to generate complementary regions of OH—Si(100) and H—Si(100) surface domains at room temperature, without causing any undesirable deformation to the Si(100) surface.

The oxidation process of silicon at room temperature is not only sensitive, but the specific role played by potential oxidizing ions is presently not well understood. Various studies have looked at growing SiO₂ with UV light in different atmospheres saturated with either O₂, H₂O, or N₂O [A5, A6]. For example, Osipov et. al. investigated the process of silicon oxidation in an O₂ atmosphere under laser irradiation at 157 nm and found that O⁻ ions are primarily responsible for the transport of oxygen through a growing oxide layer [A4]. Additionally, it was found that the oxidation reaction at the interface proceeds so fast that the diffusion and recombination of the oxidizing species limits the surface oxidation process. The rate of recombination was shown to be proportional to the squared concentration of the oxidizing species. Patzner et. al. found a similar loss of oxidizing species when using an atmosphere saturated with H₂O, with molecules preferably reacting with defects in the amorphous oxide film instead of interacting with the underlying surface [A7]. To prevent the diffusion of oxidizing species, Kailath et. al. diluted their O₂ concentration with nitrogen when oxidizing H—Si(100) with a Nd:YAG laser at 355 nm [A8]. Consequently, they were able to control the growth of SiO₂ up to 0.86 nm. Thus, it seems that there may be benefit in generating a vacuum-based laser-assisted oxidation technique where a limited concentration of introduced oxidizing species prevents significant SiO₂ growth and thus hinders the fast rate of diffusion and recombination that stimies oxidation of the underlying silicon surface.

There have been many other reports that studied the mechanism of oxide formation by laser-assisted oxidation [A4, A9-A11]. However, the photoinduced oxidation kinetics is not well understood. The use of continuous wave lasers to directly oxidize silicon was first reported by Gibbons [A12]. In an attempt to enumerate a possible oxidative mechanism, Boyd et al. proposed that the increased carrier population due to the absorption of continuous laser radiation weakens more Si—Si bonds and enhances the rate of oxidation [A3, A13]. Nayar et. al. and Orlowski and Mantell have reported that oxide growth is due to the self-limiting diffusion of O atoms produced by photo dissociation of O₂ [A9, A14]. However, in all these reported techniques the substrate was maintained at a higher temperature (673-748 K). Although, a low temperature mechanism of oxidation remains unclear for both continuous and pulsed UV laser radiation, what is evident from this study is that a laser-assisted oxidation technique can be tailored to dump just enough energy onto Si(100) to enable the oxidative transformation in a localized spot. Aygun et. al. found that optimal Si(100) oxidation by laser-assisted oxidation occurs just below the laser induced damage threshold (LIDT) of the material [A11]. It is not clear what the possible energy dissipation outside the laser exposure sites would be at these higher fluences. Nor is it clear the minimal energy density at which point the increased rate of oxidation is first observed. Regardless, considering the demands of modern microelectronics one can conclude that the Nd:YAG laser-assisted oxidation is a promising technique for the formation of small-spot oxide. Although we do not yet understand the oxidation mechanism exactly and the results raise many questions about the growth process, Nd:YAG laser oxidation was shown to produce good quality oxide layers for device applications.

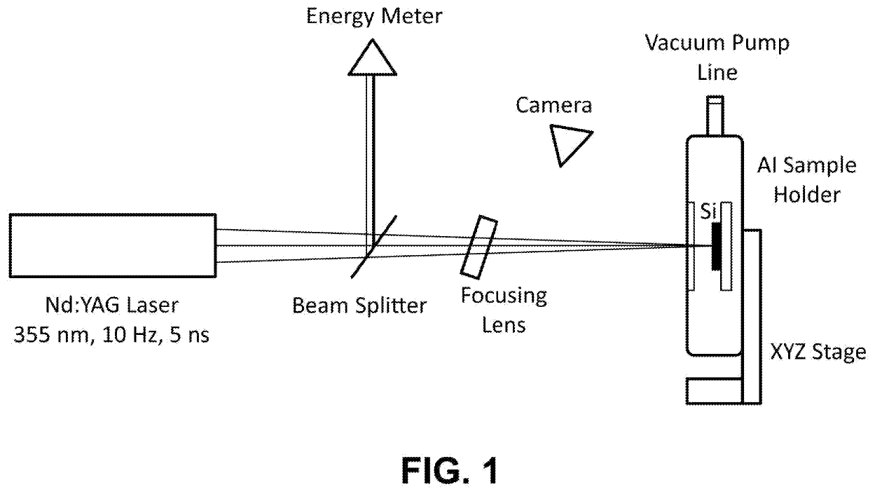

Results and Discussion: The Si substrates used were p-type (100) oriented wafers. A 4 cm² Si(100) substrate was rinsed with isopropanol alcohol and ultra-pure water. The substrate was then cleaned chemically in Nano-Strip for 15 min and then immersed in hydrofluoric acid (5%) for 6 min to chemically etch away the native oxide layer and form H—Si(100). The substrate was then rinsed with isopropanol and dried under nitrogen gas. The substrate was then mounted on copper tape underneath a quartz window inside the sample holder. The chamber inside the holder was evacuated to 10⁻⁷ torr. The laser treatment was carried out using Nd: YAG radiation at 355 nm (Quantel Pulsed Laser NL301). The laser parameters are summarized in Table 1. A schematic illustration of the experimental apparatus is shown in FIG. 1.

TABLE 1
Laser Parameters

| | Pulse | Pulse Energy | Pulse | Beam | Beam |
|---|---|---|---|---|---|
| Wavelength | Duration | Density | Profile | Height | Width |
| 355 nm | 5 ns | 0.50-0.70 | Vertical | 1.5 mm | 1.0 mm |
| | | J/cm² | Oval | | |

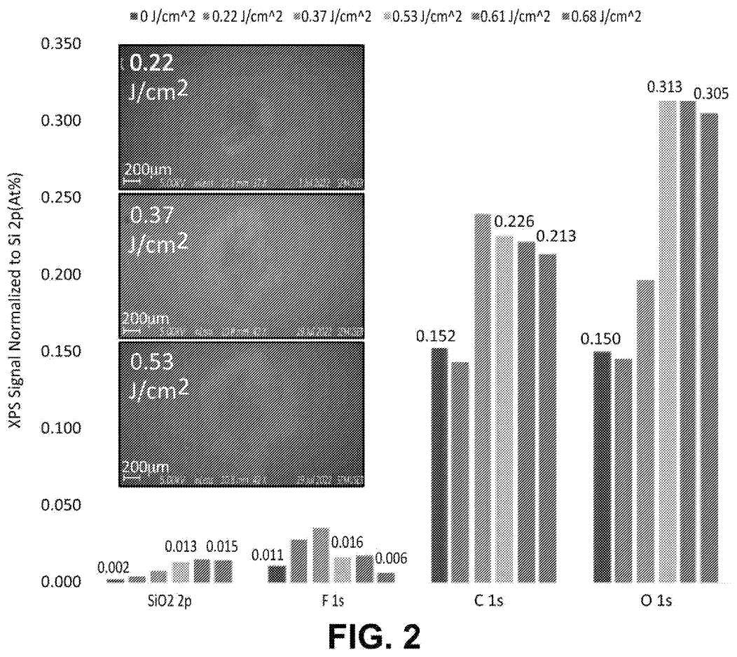

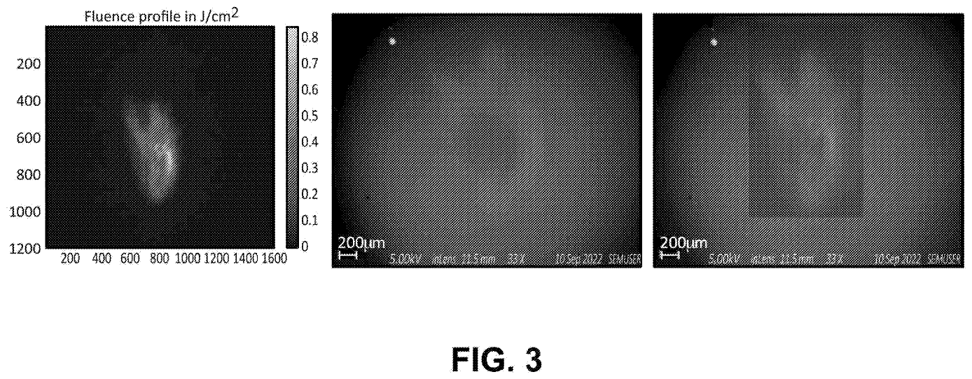

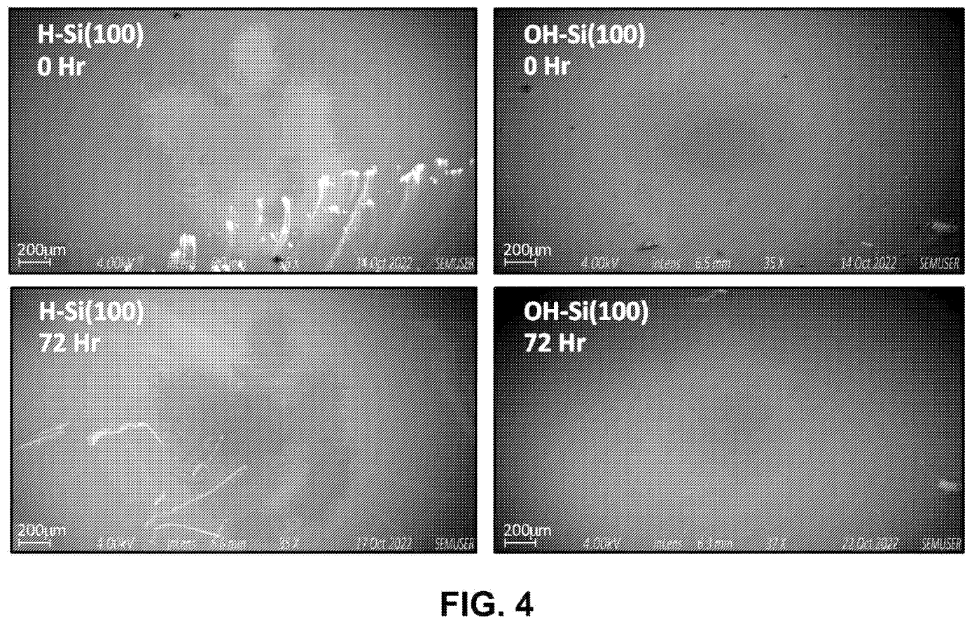

The laser beam has a declining intensity profile with the maximum intensity occurring on the left edge and dropping one order of magnitude across the entire width of the beam. The main experimental laser fluence varies in the range between 0.1 and 1.0 J/cm² per pulse, with a significant increase in oxidation observed starting at 0.5 J/cm². Results are shown in FIG. 2-FIG. 4.

There would be great utility in constructing a similar technique for the laser-assisted oxidation of organic layers on Si(100). These photopatterned species could act as robust molecular resists for subsequent deposition process such as AS-ALD. It is important to find a chemistry that maintains the excellent physical and electrical properties of Si(100), while inhibiting partial oxidation outside the laser exposed sites and improving ALD growth selectivity.

Oxidative and interface properties vary strongly with the type of Si surface used. Si(100) is often selected as a suitable substrate material as it can tightly bind atoms in complex arrangements while maintaining conductivity at higher temperatures. In the (100) orientation, the Si/SiO₂ interface state density is generally lower compared to that of (110) and (111) oriented wafers. This results in a lower amount of dangling bonds and thus, a higher carrier mobility and/or drive current desirable in most Si-based electronics. However, on Si(111) laser-assisted oxidation has been shown to form a thicker suboxide interface layer which demonstrates improved insulating behavior and better protects the underlying surface from thermal effects. Thus, some applications may find the refinement and enumeration of a laser-assisted oxidation technique of H—Si(111) beneficial. The quality of the small spot oxide layers on either Si(100) or Si(111) can be further improved by optimization of the process parameters. The thickness uniformity, dielectric and electrical properties of the spots can further affect the process results.

### REFERENCES

A1. Green M L et al., Ultrathin (<4 nm) SiO₂ and Si—O—N gate dielectric layers for silicon microelectronics: Understanding the processing, structure, and physical and electrical limits. Journal of Applied Physics, 2001. 90(5): p. 2057-2121.
A2. Grayson A C R et al., A BioMEMS review: MEMS technology for physiologically integrated devices. Proceedings of the Ieee, 2004. 92(1): p. 6-21.
A3. Boyd I W et al. Laser Processing of Silicon. Nature, 1983. 303(5917): p. 481-486.
A4. Osipov A V et al. Kinetics of laser-induced oxidation of silicon near room temperature. Applied Physics a-Materials Science & Processing, 2006. 82(2): p. 275-280.
A5. Orlowski T E et al. Ultrafast Laser-Induced Oxidation of Silicon—a New Approach Towards High-Quality, Low-Temperature, Patterned SiO₂ Formation. Applied Physics Letters, 1984. 45(3): p. 241-243.
A6. Jin Y G et al. Mechanism for the enhanced diffusion of charged oxygen ions in SiO₂. Physical Review Letters, 2001. 86(9): p. 1793-1796.
A7. Patzner P et al. Photoinduced self-limited low-temperature growth of ultra-thin silicon-oxide films with water vapor. Applied Physics a-Materials Science & Processing, 2006. 85(2): p. 145-150.
A8. Kailath B J et al., Growth of ultra-thin SiO₂ by laser-induced oxidation. Semiconductor Science and Technology, 2009. 24(10).
A9. Nayar V et al., Low-Temperature Oxidation of Crystalline Silicon Using Excimer Laser Irradiation. Applied Surface Science, 1989. 36(1-4): p. 134-140.
A10. Cros A et al. Laser-Induced Oxidation of the Si(111) Surface. Applied Physics a-Materials Science & Processing, 1982. 28(4): p. 241-245.
A11. Aygun G et al., Oxidation of Si surface by a pulsed Nd: YAG laser. Journal of Physics D-Applied Physics, 2004. 37(11): p. 1569-1575.
A12. Gibbons J F. Applications of Scanning Cw Lasers and Electron-Beams in Silicon Technology. Japanese Journal of Applied Physics, 1980. 19: p. 121-128.
A13. Boyd I W. Laser-Enhanced Oxidation of Si. Applied Physics Letters, 1983. 42(8): p. 728-730.
A14. Orlowski T E et al. Ultraviolet Laser-Induced Oxidation of Silicon—the Effect of Oxygen Photodissociation Upon Oxide-Growth Kinetics. Journal of Applied Physics, 1988. 64(9): p. 4410-4414.

### Example 3

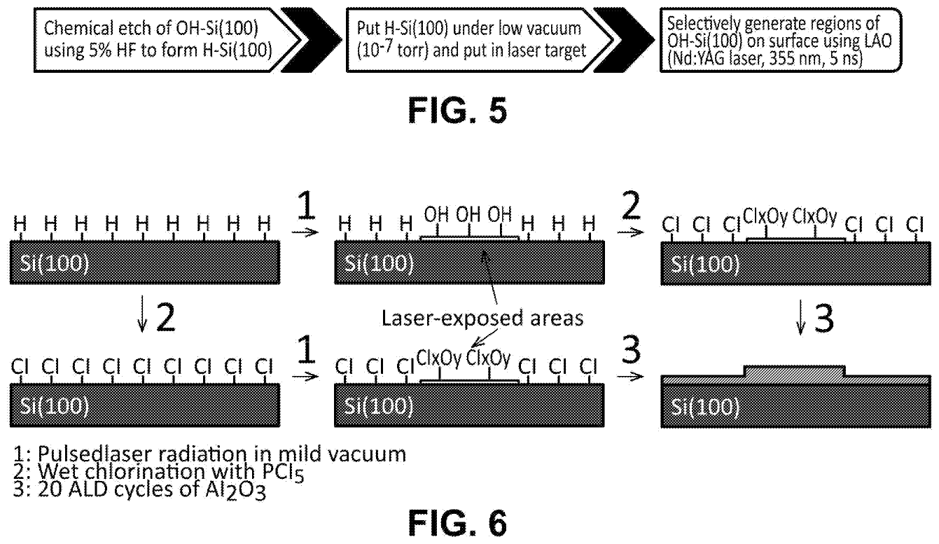

Described herein are methods to selectively increase the rate of oxidation on hydrogen-terminated Si(100) using Nd:YAG laser-assisted oxidation (LAO) under low vacuum and at room temperature, as shown schematically in FIG. 5.

What results is the patterned formation of small-spot oxides with moderate resolution and good oxide quality. The methods can include subsequent deposition strategies which involve various chemistries to exploit differences in reactivity between selectively irradiated OH—Si(100) regions and surrounding H—Si(100) surface for passivation and/or fabrication of multilayer devices.

After selectively oxidizing localized spots on Si(100), the patterned OH—Si(100)/H—Si(100) substrate can be functionalized with a resist in order to realize patterned deposition, as shown in FIG. 6 (top row). Alternatively, chlorinated Si(100) can also be transformed using laser-assisted oxidation, leading to subsequent patterned deposition, as shown in FIG. 6 (bottom row).

Utility and Method of Use. Laser-patterning of Si(100) substrate is a foundational platform for subsequent self-aligned fabrication schemes such as:
1. Area-selective atomic layer deposition (AS-ALD)
   a. Paired with hydroxylated Si(100) (OH—Si(100)) as the deposition area, hydrogen-passivated Si(100) (H—Si(100)) is also regularly used as a simple ALD resist valued for its uniform composition and relatively good growth/etch selectivity.
   b. Manufacture of high-resolution metal-oxide masks for device patterning
   c. Refinement of complementary metal-oxide-semiconductor (CMOS) devices
   d. Fabrication of alternative dielectrics layers with high dielectric constant (high-κmaterials)
   e. Assembly of organic-semiconductor interfaces needed in fields ranging from nanoelectronics to biosensing
2. Selective passivation of H—Si(100) for the formation of dielectric layers (i.e. generation of ultra-thin and electrically reliable SiO₂ layers on Si(100) substrate)
   a. Due to its high reactivity and low stability in air, the use of H—Si(100) is primarily confined to ultra-high vacuum (UHV) environments, which currently limits its commercialization and utilization as a foundation material for bottom-up processing. Hence, it is important to find a chemistry in which to passivate H—Si(100).
   b. Building MOS Capacitors (i.e. silicon-based MOSFETs)
   c. Formation of sub-10 nm electrical vias with sharp vertical wall profiles
   d. Construction of other Si—SiO₂ devices
3. Various other surface processing of Si(100) for fabrication of:
   a. Nanoelectromechanical systems (NEMS)
   b. Microelectromechanical systems (MEMS)
   c. Biomaterial systems

The methods described herein can address one or more of the following difficulties:
(a) The need for more precise thickness control of the oxidation process.
(b) High temperatures (upwards of 1000° C.) required for traditional silicon oxidation for the generation of SiO₂ films. High temperature processing should be avoided for MOS devices to prevent relaxation of strain.
(c) Slow rate of oxidation at low temperature.

The methods described herein can deliver just enough energy to enable the oxidative transformation in a localized spot of Si(100), without dissipating the energy to the outside areas.

### Example 4—Laser Induced Patterning of Molecular and Atomic Level ALD Resists

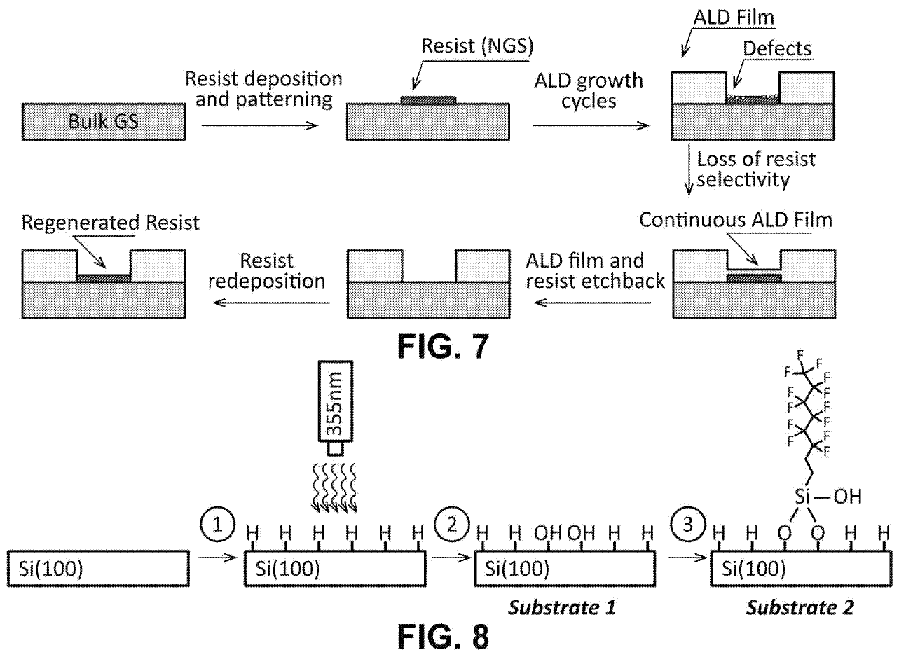

The future generation of atomically precise and ultra-efficient opto-electronic and quantum devices will rely on 3D architectures that are accessible via bottom-up processes such as area-selective atomic layer deposition (AS-ALD) (FIG. 7) and atomic layer etching (ALE).

One of the major challenges of bottom-up manufacturing that preclude widespread AS-ALD/ALE implementation is the lack of unifying conditions and patterning methods that are universally compatible with different materials and device architectures.

There exists a need for a universal method of atomic/molecular resist deposition on a wide variety of substrates. Traditionally, AS-ALD resists and methods are designed for specific substrate-chemistry combinations. A universal resist material will greatly expand the applicability of ALD to various types of device material and architectures

There exists a need for a universal resist patterning method applicable to different substrates. Patterning of the AS-ALD resists is usually performed using highly resist-substrate specific, low-resolution methods incompatible with the ALD conditions.

Existing ALD resist patterning techniques are summarized in Table 2.

TABLE 2
ALD resist patterning techniques.

| Technique | Resist | Advantage | Disadvantages |
|---|---|---|---|
| Photo- | Polymeric | High-throughput/ | Incompatible with |
| lithography | (photoresists) | mature | molecular/atomic |
| | | | resists |
| Shadow-mask | Inorganic | High-throughput/ | Resolution, |
| deposition | thin films | mature | resists types |
| STM | Atomic and | Highest | Low-throughput/ |
| | molecular | resolution/resist | UHV |
| | | universal | |
| Transfer | Thin film/ | Low-cost | Resolution/ |
| printing | molecular | | reproducibility |
| CW Laser | Polymeric | | Energy dissipation |
| writing | | | and resolution |
| Pulsed laser | Polymeric/ | Direct energy | |
| writing | molecular/ | transfer/ | |
| | atomic | universal | |

Described herein are methods for pulsed laser modification of atomic or molecular resists. A schematic illustration of the method is shown in FIG. 8. The methods include one or more of the following:
1. Localized energy delivery.
2. Fast reaction times. Thermal activation of Si—H in high boiling point solvents requires tens of hours of reaction time, Hg lamp (254 nm) activation reduces the reaction time to hours. Pulsed laser activation can achieve almost instantaneous reaction times by adjusting the laser fluence.
3. Path towards direct resist photodissociation via multiphoton absorption with near UV or visible light. Femtosecond exposures increase the cross-section of multiphoton absorption and can lead to direct substrate-resist bond photo-dissociation without heating the substrate. Near UV and visible light illumination is compatible with traditional quartz and fused silica optics (no need to use CaF₂ optics required in 172/193 nm excimer laser systems)
4. Compatibility with scanning/writing systems
5. Compatible with UHV equipment. Patterning and exposure can be performed through the window and the reactive component can be introduced through the ALD/ALE flow control system. Scanned laser exposure does not require a photomask positioning and alignment system.
6. Mechanistically similar to the STM experiments. The reaction proceed through homolytic Si—H bond cleavage (high activation energy) or transition-state induced mechanisms (lower activation energy). STM parameters (voltage, current density) can be correlated with the photo-exposure parameters (wavelength, fluence, pulse length).

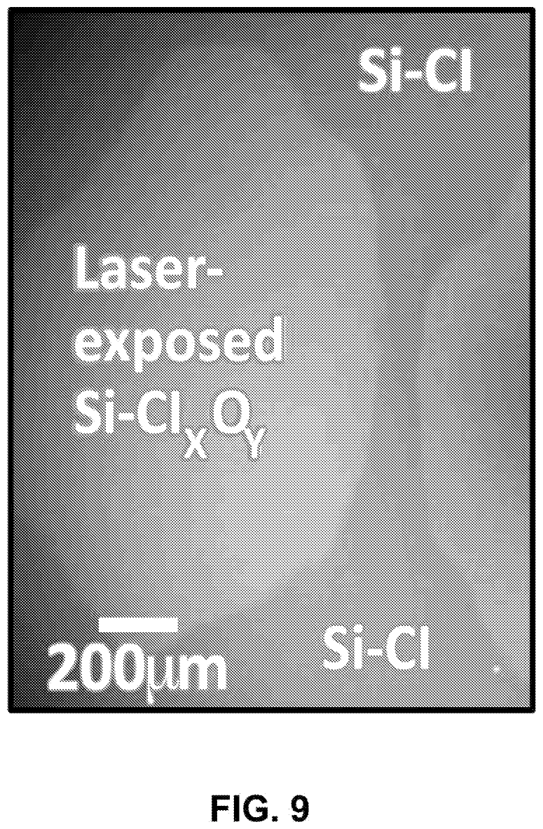

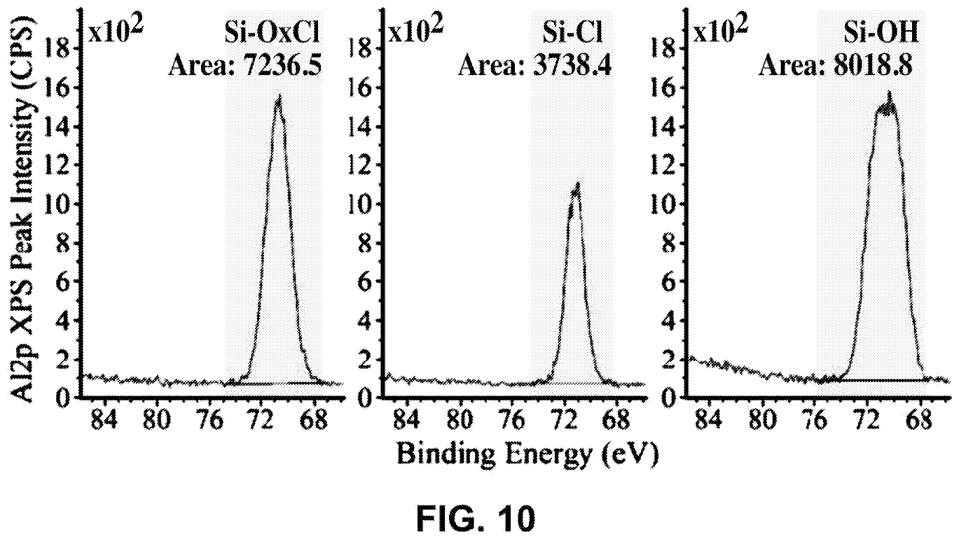

For example, the laser induced patterning of Si—Cl substrates and ALD of Al₂O₃ is shown in the bottom row of FIG. 6. FIG. 9 is an image of the laser patterned Si—Cl substrate (24 nm, 5 ns, 0.8 J/cm²). The Al₂O₃ content of laser-exposed, unexposed, and control samples were analyzed via XPS (FIG. 10).

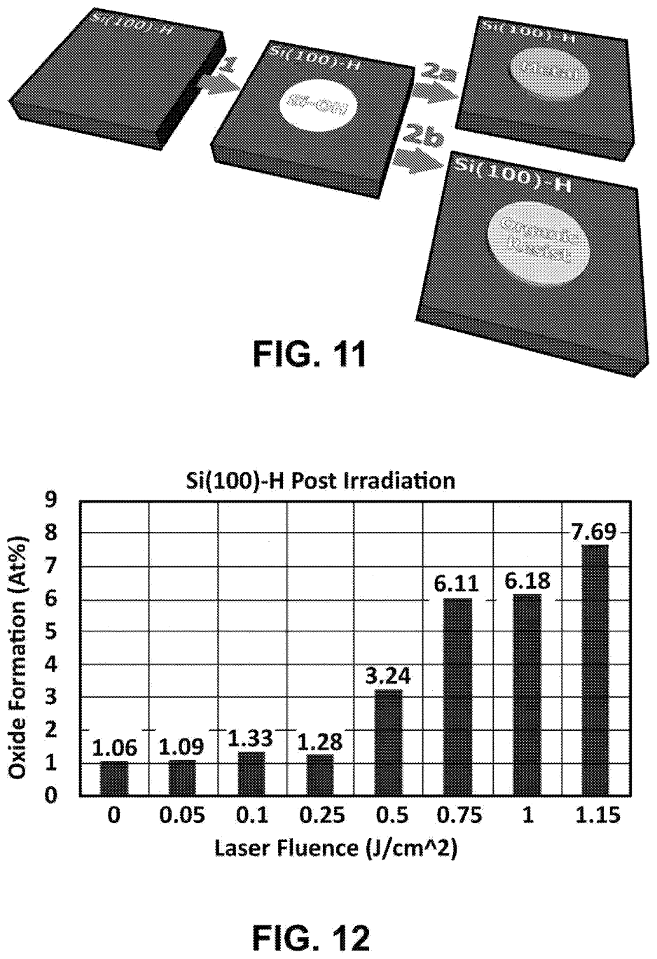

The laser-patterned substrate can be used with a variety of deposition methods, such as ALD and CVD. For example, the methods can comprise photo-initiated oxidation of Si(100)-H followed by self-aligned ALD of metal and/or metal oxides on Si—OH or self-aligned CVD of an organic molecular resist (FIG. 11). The laser fluence can affect the oxide formation (FIG. 12).

### Example 5—Harnessing Light—Substrate Interactions for Promoting Selective Oxidative Growth on Silicon Under Low Vacuum

ABSTRACT. Described herein is a technique for patterning thin oxide layers on hydrogen-terminated silicon (H—Si(100)) using Nd:YAG pulsed laser radiation (355 nm, 5 ns) under low vacuum and room temperature conditions. The exposure wavelength was selected to limit photon absorption to a ~5 nm depth below the Si—H interface, while the 5 ns pulse length was selected to ensure linear absorption and a broad operational range of laser beam peak intensity. By controlling the peak intensity and overall fluence, this technique can effectively promote a large number of surface electrons to excited states without depositing a significant amount of energy into the bulk material. A range of laser beam fluences (0.25-0.70 J/cm²) was identified where the oxidation of H—Si(100) was promoted without causing physical damage or crystallographic modification of the substrate. Contrastingly, the same laser-induced exposures produced limited physical and chemical changes on an already oxidized OH—Si(100) surface, verifying that laser-initiated energy transfer is the primary source of the surface oxidation effect observed on H—Si(100). X-ray photoelectron spectroscopy (XPS) demonstrated that the surface concentration of oxide on H—Si(100) increased with laser fluence relative to the surrounding unirradiated surface. Grayscale analysis of the laser beam profiles paired with scanning electron microscopy (SEM) imaging of the exposure sites revealed that this laser-assisted oxidation effect proceeds in a threshold manner (e.g., a thin ~1 nm oxide layer develops after exposure with a threshold fluence value), and that the increasing laser fluence (up to the physical damage threshold of Si(100)) does not lead to the formation of thicker oxide films. These findings suggest that the oxidation effect proceeds differently than from what would be observed from a predominantly thermal-based mechanism, where the thickness of the oxide layer would continue to increase with time and temperature up to a standard native oxide depth. Atomic force microscopy (AFM) analysis was also used to verify that the small oxide spot patterns were formed via chemical transformation and not physical modification of the Si(100) substrate. Lastly, ambient stability studies over 72 hours demonstrated that subsequent passive oxidation within the irradiated spots progressed differently than on the background non-irradiated area, indicating that laser radiation grows a different form of oxide (most likely Si₂O₃) than that of stoichiometric SiO₂. From these results it was concluded that pulsed laser exposures of a monoatomic hydrogen layer on Si(100) can promote chemical oxidation of silicon without causing morphological damage to the underlying surface. This technique has the potential to open up manufacturing pathways for universal activation of mono-atomic and mono-molecular interfaces.

INTRODUCTION. According to the Semiconductor Industry Association (SIA), the total consumption of electricity by electronic devices will surpass global energy production by 2040 [B1] unless radical changes are made in the efficiency, design, and manufacturing of electronic device components. The current trend can be avoided by inventing new technologies and device architectures that are more efficient and improve chip performance through hierarchical 3D designs, so-called “More-than-Moore” (MtM) technologies, rather than by relying on unsustainable 2D scaling, such as shrinking transistors. Such 3D chip architectures are predominantly accessible via bottom-up device processes that rely on mono-atomic and/or mono-molecular film deposition, etching and patterning steps to build and assemble device components in an additive manner via precise and self-aligned surface chemical reactions. To enable such manufacturing, recently there has been an emphasis on finding universal and reliable techniques for controlling and modifying chemical reactivity of atomic and molecular films on semiconductor materials [B2]. Through surface chemical modification, these nanometer-scale systems can be tailored to incorporate various active device components such as patterned ultra-shallow doping layers [B3], chemo-selective resists for area-selective atomic layer deposition (AS-ALD) and atomic layer etching (ALE) [B4], or chemical and biological templates for sensors and molecular arrays [B5]. However, one of the major challenges of nanofabrication that precludes widespread implementation of mono-atomic and mono-molecular platforms is the lack of unifying conditions for controlling and activating chemical reactivity of these systems in a spatially resolved manner on a variety of different films and substrates.

The patterning and deposition of small molecular films has typically relied on various renditions of microcontact printing [B6, B7], which limits the resolution of printed features to a micrometer range due to molecular diffusion. In the past, a diffusion-less stamping method for patterning organic molecules with sub-50 nm resolution was developed, but it remains specific to certain functional groups only [B6, B8] and is also incompatible with vacuum-based deposition or etching. To date, atomic level patterning has been enabled mostly with scanning tunneling microscopy (STM) where the tunneling current between the STM tip and the conductive substrate is used to selectively remove surface atoms before replacing them with other active species [B9]. Although STM demonstrates atomic-scale precision, it is limited by extremely low throughput and requires energy-intensive processing to control the cryogenic and ultra-high vacuum (UHV) conditions necessary for the patterning environment. Whereas STM initiates patterning using a flux of electrons to homolytically cleave surface bonds, it is hypothesized that it is possible to achieve a similar transition-state-induced effect by delivering energy via a photon flux. By concentrating a high concentration of photons just within a shallow adsorption depth beneath an interface, it is hypothesized that surface atoms can be excited, leading to increased surface reactivity, but without dissipating energy into the bulk substrate. Such laser-initiated chemical activation of atomic or molecular films can promote a variety of surface reactions if the gas-phase environment around the substrate has specific chemical reactivity.

There are several advantages of using photons to initiate chemical modifications of the semiconductor interfaces. Like STM, this technique would not be limited to specific atoms or molecules and instead will activate surface electrons that are brought into excited states by controlling the peak intensity and overall fluence of exposure. Unlike STM, pulsed laser surface processing can be undertaken in a large-area and one-step nature, depending on beam size and uniformity. This increase in throughput would result in a significant decrease in energy consumption relative to STM patterning. Moreover, laser activation can be used on non-ideal interfaces, which are incompatible with STM. To gain finer control over the photon energy transfer to surface atoms/molecules and to reduce the overall energy requirement, localized pulsed laser radiation was employed instead of continuous wave (CW) irradiation where high overall fluence promotes bulk substrate heating and physical damage. Pulsed laser-assisted ionization of organic molecules is a well-known phenomenon that is used in various analytical techniques, and when combined with photomask patterning, can achieve the same resolution as current state-of-the-art photolithographic processing [B10]. Additionally, scanning laser systems are also scalable to conventional wafer-size substrates [B11] and can potentially be implemented in vacuum-based processes, enhancing the adaptability and compatibility of pulsed-laser activation in diverse manufacturing environments.

A form of laser-assisted chemical transformation that is easy to monitor on a surface is that of oxide generation. Oxidation of silicon is an important topic in microelectronics [B12], surface passivation [B13], and bio-engineering [B14]. Current methods primarily aim at producing a continuous SiO₂ thin film, often requiring high processing temperatures [B15-B17]. Consequently, there has been a longstanding pursuit to find an approach that can achieve (1) localized silicon oxidation with high spatial resolution, (2) operate at lower processing temperatures, and (3) avoid introducing crystallographic damage to the surface. To gain better control of the oxidation process at low temperatures, researchers have turned to various growth techniques such as ion-beam, plasma, visible and ultraviolet (UV) radiation [B18, B19]. Of these techniques, oxide generation by UV light via pulsed laser exposures seems particularly promising for achieving these objectives. Specifically, pulsed UV laser-assisted oxidation of silicon has garnered attention due to its ability to precisely control the growth of extremely thin silicon oxide layers on the scale of 1-2 nm [B16-B18]. These studies however, primarily focused on growing continuous homogeneous oxide films without demonstrating spatial patterning or investigating the mechanism of the laser-assisted oxidation. Hence, reported herein are findings using a Nd:YAG laser system (355 nm, 5 ns) to generate the patterned formation of small-spot oxides on otherwise H—Si(100) with moderate resolution and good oxide quality at room temperature, and without causing any undesirable deformation to the underlying lattice. These laser-patterned substrates have the potential to be integrated into a wide variety of deposition strategies which involve various chemistries to exploit differences in reactivity between the selectively irradiated OH—Si(100) regions and surrounding H—Si(100) surface for passivation and/or fabrication of multilayer devices.

MATERIALS AND METHODS. All reagents and solvents were used as received without further purification. Solvents were purchased from Sigma-Aldrich and filtered through a 0.2 m filter before use. P-doped, monocrystalline (100) silicon substrates were purchased from University Wafer, Boston, Massachusetts. XPS spectra were recorded on a Kratos Axis Ultra XPS spectrometer equipped with a Al Kα (1486.6 eV) X-ray source at 200 W power and a pressure of 3.0×10⁻⁸ mbar. Survey scans were obtained between 0 and 1200 eV with a step size of 1 eV, a dwell time of 200 ms, and a pass energy of 140 eV averaged over 2 scans. Core-level region scans were obtained at the corresponding binding energy ranges with a step size of 0.1 eV, an average dwell time of 260 ms, and a passing energy of 20 eV averaged over 10 scans. XPS data was processed using CasaXPS software and instrument-specific atomic sensitivity factors. All C is peaks were calibrated to 284.7 eV and this same binding energy shift was applied to all other spectra to account for adventitious carbon contamination. SEM images were recorded on a Zeiss Auriga FIB-SEM microscope detecting secondary electrons at 2-4 mm working distance. AFM images were recorded on a NT-MDT AFM Microscope using a silicon nitride probe (Manufacturer: NanoWorld) with a tip radius of <15 nm, a resonance frequency of 67 kHz, and a force constant of 0.32 N/m. The same probe was used for each sample in tapping mode. All goniometry analysis was gathered using ultra-pure water.

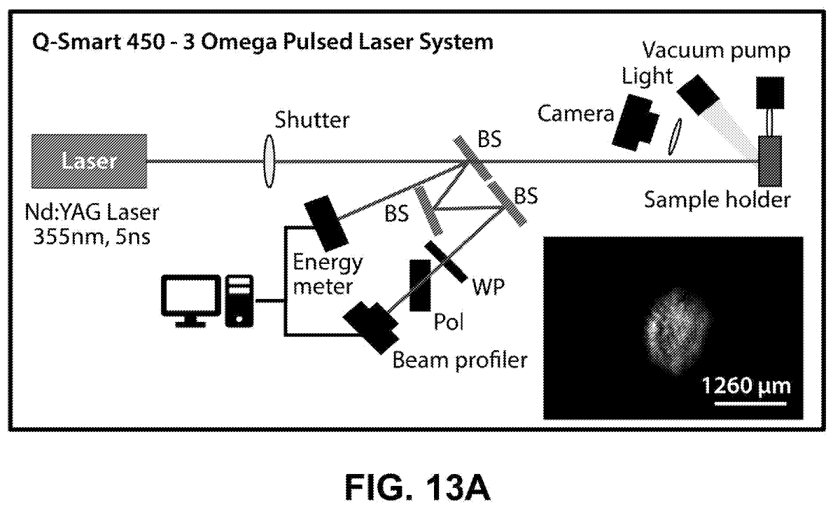

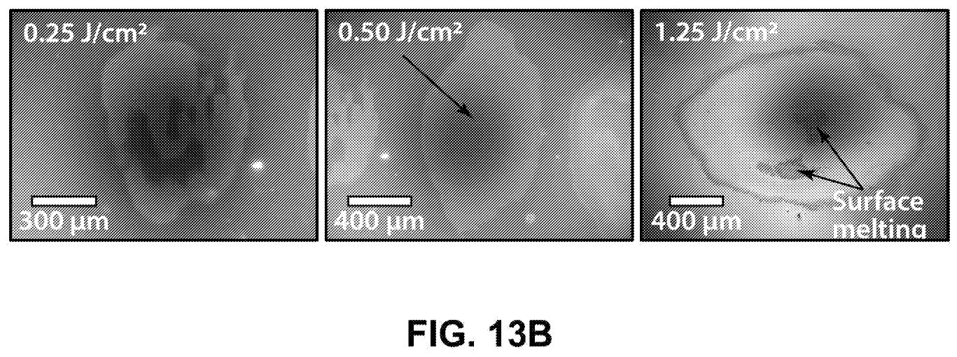

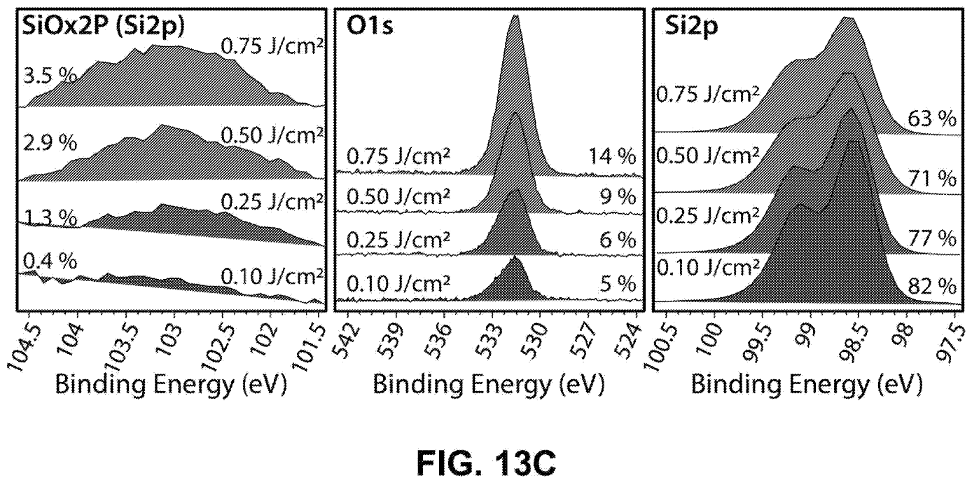

Laser Parameters and Operation. Laser treatment was carried out using Nd:YAG radiation (Q-Smart 450-3 Omega Pulsed Laser System). The laser parameters are summarized in Table 3. A schematic illustration of the experimental apparatus is shown in FIG. 13A.

TABLE 3
Laser Testing Parameters

| | Pulse | Pulse Energy | | Incident | Pulse | Beam | Beam |
|---|---|---|---|---|---|---|---|
| Wavelength | Duration | Density | Polarization | Angle | Profile | Height | Width |
| 355 nm | 5 ns | 0.25-1.25 | P | 7° | Vertical | 1.5 | 1.0 |
| | | J/cm² | | | Oval | mm | mm |

The laser beam has a varying intensity profile with the maximum intensity occurring on the left edge and dropping one order of magnitude across the entire width of the beam as seen in the insert in FIG. 13A. The main experimental laser fluence varies in the range between 0.1 and 1.0 J/cm² per pulse, with a significant increase in oxidation observed starting at 0.25 J/cm². Laser fluence was controlled using a polarizer and a rotating waveplate. A shutter was used to isolate single shots and a beam profiler and energy were used to map energy density across the sample exposure area.

Sample Preparation. All glassware was washed with 1× Nano-Strip solution (a stabilized formulation of sulfuric acid and hydrogen peroxide) followed by rinsing with water and isopropanol before being dried in an oven overnight at 130° C. A 4 cm² Si(100) substrate was soaked in Nano-Strip at 75° C. for 15 min to produce a hydroxyl-terminated surface (OH—Si(100)). Following this oxidation, the substrate was then immersed in a 5% aqueous hydrofluoric acid (HF) solution for 6 min to chemically etch away the native oxide layer and form hydrogen terminated silicon (H—Si(100)). The substrate was then quickly rinsed with water and isopropanol and dried under a filtered nitrogen gas, before being mounted in a vacuum holder (10⁻² torr) underneath a silica viewport. This holder was then placed on the target stage of the laser system, where the laser exposure beam travels through the viewport and makes contact with the H—Si(100) surface.

Estimating SiO₂ Film Thickness. From the XPS data SiO₂ film thickness was calculated using Equation 1 [B20]:

$${d}_{{SiO}_{2}} = - {λ}_{{SiO}_{2}} ln ( \frac{{I}_{S i}}{{I}_{Si , 0}} )$$

where d_{SiO}_{₂} is the thickness of the SiO₂ film, λ_{SiO}_{₂} is the photoelectron mean free path through SiO₂, and lastly I_{Si,0} and I_{Si} are the Si2p peak intensities before and after laser exposure, respectively. A photoelectron mean free path of 10 nm was used for Si2p electrons passing through SiO₂.

RESULTS AND DISCUSSION. Initial experiments were conceived to explore varying laser parameters to gain a finer control and understanding over the laser energy transfer to the H—Si(100) resist and underlying Si—Si surface. The parameters investigated were the laser pulse duration, pulse intensity and wavelength. Depending on these parameters, certain surface interactions such as photoinduced reactions, bond dissociation and/or thermal-based diffusion or phase-transition can be enabled. Thus, it is important to select conditions which effectively pattern the H—Si(100) resist with small-spot oxides without initiating diffusion, annealing, or crystallographic damage to the substrate (e.g., exposures below the damage threshold). To avoid these effects, the laser parameters shown in Table 3 were ultimately selected to limit the absorption depth of laser radiation to the top 5-10 nm of the substrate material, where most of it could be harnessed to enable chemical transformation. This is important as the absorbance coefficient of silicon is relatively high compared to most semiconductors. Pulse lengths on a nanosecond scale were selected over shorter exposure timescales in order to exert more precise control over laser fluence and decrease the likelihood of nonlinear absorption, which would prove difficult to consistently reproduce and model. All exposures were a single pulse as this allowed for only the study of the effect of varying laser fluence. Lastly, the effect of laser pulse intensity on Si(100) oxidation was examined by varying fluence exposure from 0.10 J/cm² to 1.25 J/cm² and the results are shown in FIG. 13B-FIG. 13C.

The XPS and SEM results shown in FIG. 13B and FIG. 13C, respectively, demonstrate that pulsed laser exposure of a H—Si(100) resist promotes chemical oxidation within the irradiation site without causing physical surface damage. This is evidenced by the clear enhancement of the SiOx2p XPS signal centered at 103.2 eV when a discernable amount of laser energy (0.25 J/cm²) is added to the surface compared to the surface after minimal fluence exposure (0.10 J/cm²). Quantitatively, this signal enhancement translates to an increase in SiOₓ surface concentration of 1.3 At % relative to a fully etched H—Si(100) surface. This same effect is amplified when increasing the laser fluence exposure to 0.50 J/cm² and 0.75 J/cm², with SiOₓ surface concentration increases of 2.9 At % and 3.5 At %, respectively. The relative rise in O1s XPS signal also scales very closely with SiOₓ generation. For example, between 0.50 J/cm² and 0.75 J/cm² exposures there is a 1.2× increase in SiOₓ surface concentration which shows good agreement with the 1.5× increase observed in overall O content found on the surface. Hence, the primary mode of 0 atom introduction onto the surface appears to be through SiOₓ generation. Furthermore, there are two notable characteristics in how the Si_{Bulk}2p spectra evolve with increasing fluence exposure which are indicative of interfacial chemical transformation. First, the overall Si_{Bulk}2p signal decreases, and secondly, there is a blurring of the closely spaced spin-orbit components, both of which would occur as an oxide (and other oxygenated species) accumulates on the surface, due to increasing attenuation of the underlying Si_{Bulk}2p signal. All this is strong evidence of a precise LAO effect on H—Si(100). However, if the minimum fluence threshold for this effect is approximately 0.25 J/cm², then it is also important to identify a maximum fluence where physical surface damage begins to occur. Correspondingly, LIDT testing of Si(100) determined that the surface morphology begins to physically alter starting at 0.76 J/cm², where subtle scattering of surface particles is first observed on camera. Although this damage is minimal at first, when the exposure fluence reaches 1.25 J/cm², significant surface melting will occur, as shown in FIG. 13B. Thus, the apparent range of tunable energy density available for controlling the damage free oxidation of H—Si(100) is somewhere from 0.25 J/cm² to 0.75 J/cm², with clear surface damage occurring as the fluence approaches 1.25 J/cm².

SEM imaging in FIG. 13B shows the gradual formation of the beam imprint onto the sample surface with increasing laser fluence, the generation of which scales closely with the increase in both SiOₓ2p and O1s XPS signals with fluence. This suggests that the propagation of the beam imprint in SEM is due to a change in surface termination, and therefore a change in surface charging, rather than a change in the physical morphology of the surface. AFM imaging also validates this interpretation, as no significant increase in roughness was observed within the laser exposure sites as compared to the surrounding unirradiated surface.

The role played by potential oxidizing agents in LAO growth processes is not well established. Nayar et al. theorized that SiO₂ growth via UV-light exposure is predominantly enabled by O⁻ ions, produced through photodissociation of oxygenated species in the surrounding environment (ionization energy of O₂: 12.0 eV) [B21], that then experience self-limiting diffusion through the growing surface oxide interface [B22]. It has been suggested that the fast rate of O⁻ recombination also limits the concentration of oxidizing species that are able to access the silicon surface [B17, B23]. To prevent this loss of surface oxidizing species, Kailath et al. found that by heavily diluting a saturated O₂ environment with N₂ when oxidizing H—Si(100) with a 355 nm laser, that they were able to hinder both oxide diffusion and recombination that stimies surface oxidation, which enabled great control over SiO₂ film growth [B16]. A similar phenomenon may also be occurring in this technique by virtue of the low-vacuum conditions (10⁻² torr) which similarly limits the concentration of available oxidizing species.

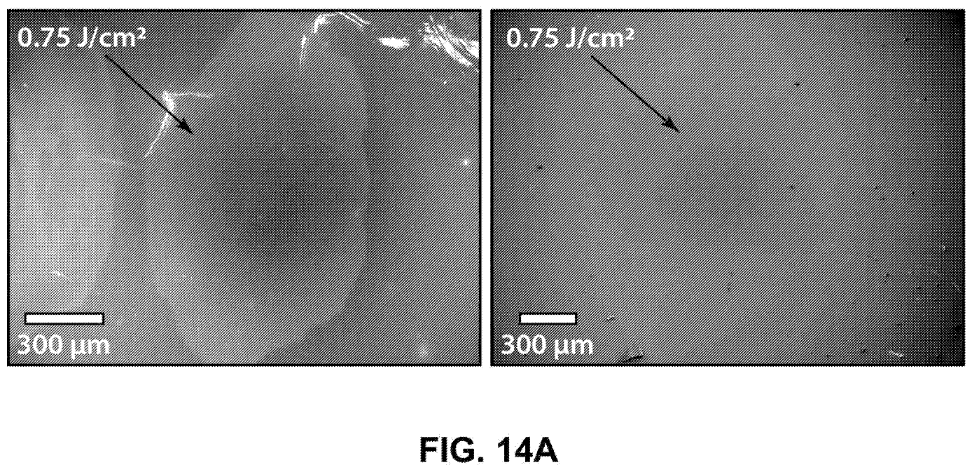

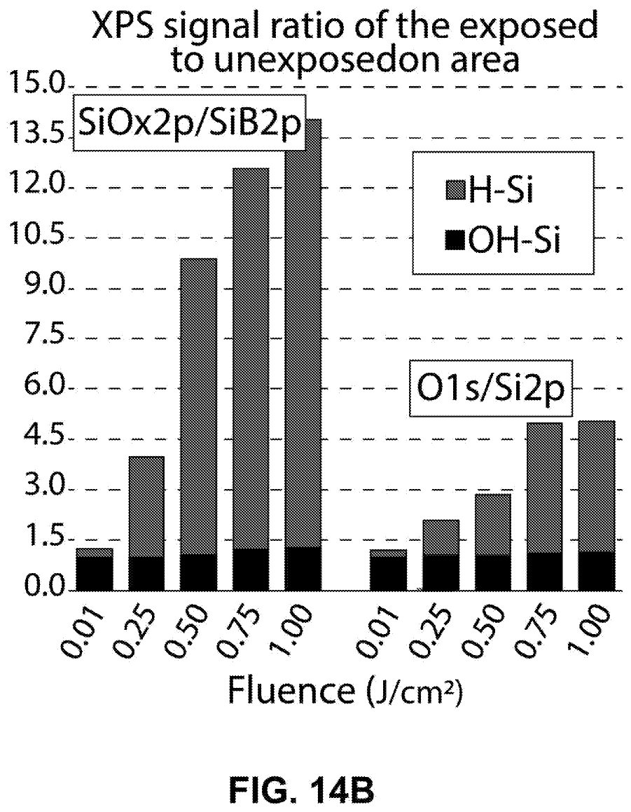

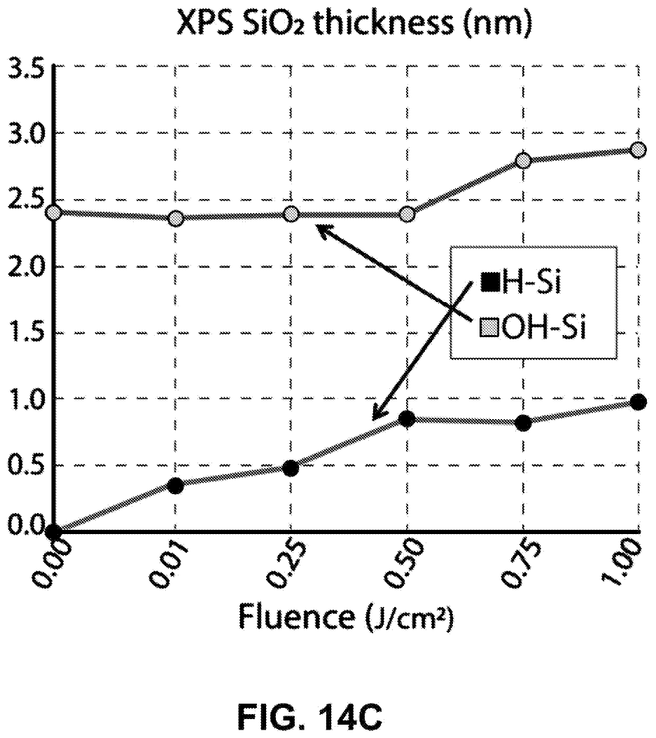

As a control experiment, the same laser exposure experiment was carried out with an already solvent-oxidized OH—Si(100) surface and a comparison between it and the laser-processed H—Si(100) sample is shown in FIG. 14A-FIG. 14C. SEM imaging shows that after exposure to 0.75 J/cm² there is clear imprinting of the laser beam onto the H—Si(100) surface, whereas the beam imprint is much harder to discern on the OH—Si(100) surface despite similar SEM detection settings, due to a smaller difference in contrast between the irradiated and non-irradiated areas (FIG. 14A). Furthermore, a histogram of showing the increase in SiOₓ2p and O1s signals on both OH—Si(100) and H—Si(100) with increasing laser fluences relative to an unexposed area, demonstrates that there is significantly more oxidative change occurring on the H—Si(100) surface as laser energy is applied (FIG. 14B). For example, after exposure with 1.0 J/cm² there is a 14 times increase in SiOₓ2p signal on H—Si(100), while the OH—Si(100) surface exhibits only a 1.4 times increase in signal between the irradiated and non-irradiated areas. Below 0.75 J/cm² exposure, on OH—Si(100) both the SiOₓ2p and O1s signals found on the irradiated sites are approximately the same found on the non-irradiated area. These observations show good correlation with the estimated SiO₂ thickness values displayed in FIG. 14C, where on OH—Si(100) an increase in thickness is only observed after exposure with 0.75 J/cm². Meanwhile, gradual growth in SiO₂ thickness is observed on H—Si(100) as more laser fluence is applied. All this is to suggest that the laser exposure is initiating a predominantly chemical modification rather than a morphological one. Furthermore, the estimated SiO₂ thickness values also show that after 0.75 J/cm² exposure on H—Si(100), the oxide thickness is still only 34% of the thickness found on the native OH—Si(100) surface. This suggests that there is still potential for an incredible degree of fine tuning using laser fluence when it comes to the LAO of H—Si(100). Lastly, although it would be expected that the relative increase in O1s signal would scale evenly with that of the SiOₓ2p signal, if only surface oxidation is occurring, this is not the case on H—Si(100). However, as can be observed in the O1s spectra in FIG. 13C, the H—Si(100) surface begins with a discernable amount of 0 surface concentration as opposed to SiOₓ, specifically, at a 0.1 J/cm² exposure site there is already 5 At % of O content, whereas there is only 0.4 At % of SiOₓ surface concentration. Therefore, with increasing laser fluence, the overall increase in O1s signal is less than that of SiOₓ2p due to higher initial amount of non-SiOₓ, 0-containing species found on the surface.

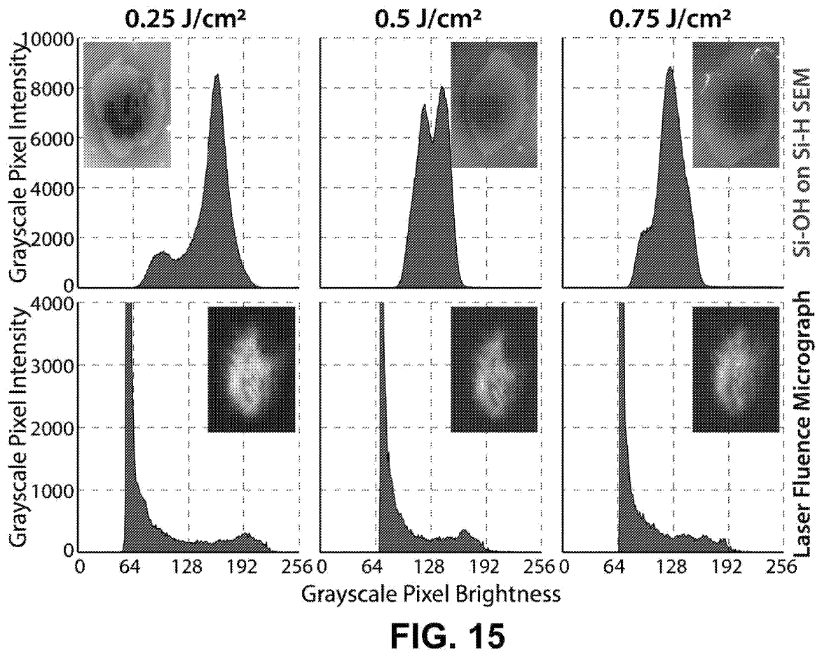

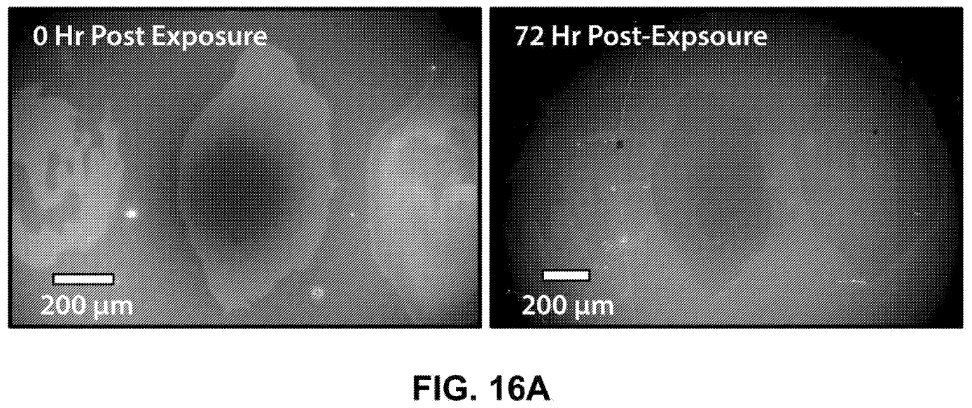

Fluence maps across the exposure area were collected using a beam profiler and converted to topographies in MATLAB™. An array of fluence maps and SEM of the corresponding exposure sites are shown in FIG. 15 and demonstrate the general uniformity of the laser beam shape and dimensions. Moreover, visual alteration of the sample surface is limited to within the beam imprint and no outside dissipation (whether chemical or physical) is observed outside the confines of the beam profile shown in the fluence mapping. Both the fluence maps and SEM images were converted into greyscale images and the pixel intensities across each image were plotted in the accompanying intensity profiles in FIG. 15. These profiles show that although the exposure sites appear to have been generated by an even distribution of laser intensity throughout the entire beam imprint under SEM (negligible change in greyscale value), the fluence maps reveal that the laser intensity in fact varied widely throughout the exposure beam as evidenced by the inhomogeneity in greyscale values charted across each fluence map. Furthermore, the intensity profiles of the SEM images demonstrate increasing homogeneity of the signal with increasing fluence, whereas the intensity profiles for the fluence maps remain non-uniform. Yet, the XPS data shown thus far has demonstrated that the degree of oxidation increases with the average fluence of the exposure beam, despite the nonuniformity in fluence profile (i.e. XPS did not capture local maximums and minimums of signal within an irradiated site). Specifically, a thin oxide layer (~1 nm) develops after a threshold fluence value and even with increasing laser fluence (up to the physical damage threshold of Si) the formation of thicker oxide films does not occur. Thus, the laser-assisted oxidation effect observed in this study appears to be a threshold event and not entirely area-specific within an exposure site. Furthermore, this also suggests that oxidation proceeds via a different route than primarily a thermal mechanism where the thickness of the oxide layers would continue to increase with time and temperature up to a standard native oxide depth (~2.5 nm).

In order to effectively modulate surface chemical reactions, it is important to understand the mechanism by which light absorption induces them. The primary potential processes are photoelectrochemical processes induced by carrier generation in the substrate, thermal processes due to substrate heating, and direct electronic absorption by the molecular species at the interface. Although there have been some general studies into the mechanism of laser-assisted oxidation of H—Si(100) [B15, B17, B22, B24, B25], the photoinduced oxidation kinetics is not well understood. Gibbons was the first to employ CW lasers to grow SiO₂ on Si(100) [B26] and in an attempt to enumerate a possible oxidative mechanism, Boyd et. al. hypothesized that the continuous laser radiation enhanced carrier population by progressively weakening surface Si dimers [B27] via promotion of valence electrons (Si bandgap: 1.12 eV) and subsequent electron-induced lattice heating. Aygun et. al. also found that optimal Si(100) oxidation by CW laser radiation occurs just below the LIDT of the material [B15], lending credence to the theory that weakening surface Si dimers are the primary driver behind surface oxidation. However, these experiments were conducted with heat being supplied to the substrate independent of the CW laser radiation, most likely resulting in a thermal diffusion effect in which oxide growth was only guided by the laser exposure. Nevertheless, using continuous laser radiation to weaken and gradually break surface bonds through a predominantly thermal effect is an example of a linear process since the probability of bond activation/dissociation increases with exposure duration. An example of a nonlinear absorption would pertain to a process where reactivity is being driven by an optical phenomenon such as one- or two-photon absorption where laser photons are absorbed by either the Si or H surface atoms, consequently bringing them to an excited electronic state. For example, Liu et al. theorized that fs laser radiation of Si(400) excited the nonlinear ionization of Si electrons via electron-induced ionization [B24](energy transformation between high-energy free electrons and bound electrons that leads to the ionization of multiple free electrons). This in turn resulted in the recombination of electron-hole defects, also weakening the Si lattice. They observed localized regions of oxidation using energy dispersive X-ray spectroscopy (EDS), however significant lattice damage was also observed. Since, increasing the duration of exposures does not correlate with an increase in probability of a process like two-photon absorption, and due to the fact that the pulse length used in this study is relatively long compared to fs and ps laser exposure systems, the probability of a nonlinear absorption process being source of the laser-assisted oxidation effect is unlikely. However, if the mechanism behind this LAO effect is due to a linear process then it is also unlikely that the energy of the photons at 355 nm (3.5 eV) for 5 ns pulses are delivering enough energy to overcome the threshold for Si—H dissociation (3.9 eV) [B28]. Yet, the Gibbs free energy of oxide formation for Si is −35.4 J/mole at ambient temperature and pressure and thus is significantly prone to oxidation in most states. Therefore, it is possible then that this short-pulse exposure of H—Si(100) leads to an excited-state absorption process where an increase in carrier density is attained that brings Si or H surface atoms into an excited state allowing for adequate surface reactivity with the surrounding low-vacuum environment. This increase in carrier population may be the result of combined electron-photon coupling and thermal (without significant diffusion) effects which activate the surface near-instantaneously upon laser exposure. Alternatively, electron-photon coupling may also induce pseudo phase-transition states that allow for higher oxidative reactivity. The proposed pulsed-laser activation achieves high efficiency by directly delivering energy required for surface film (Si—H) activation.

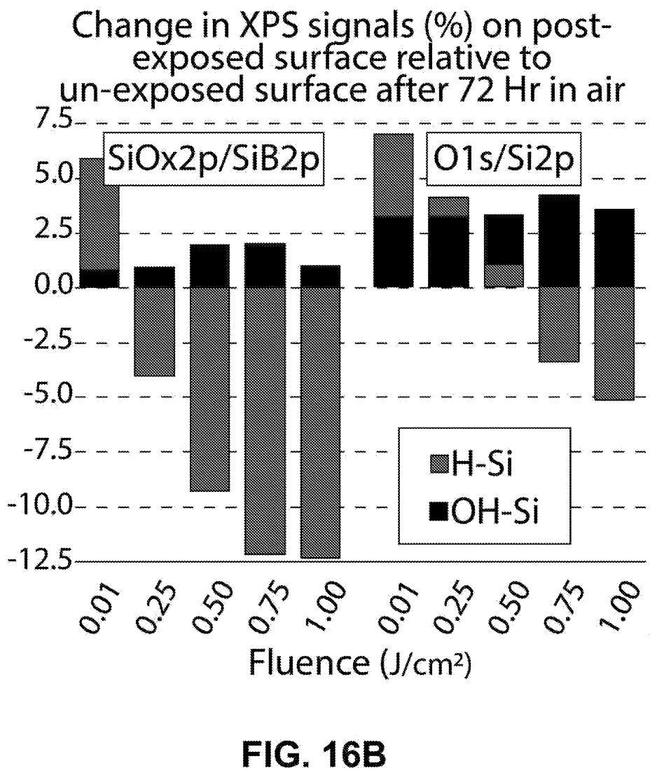

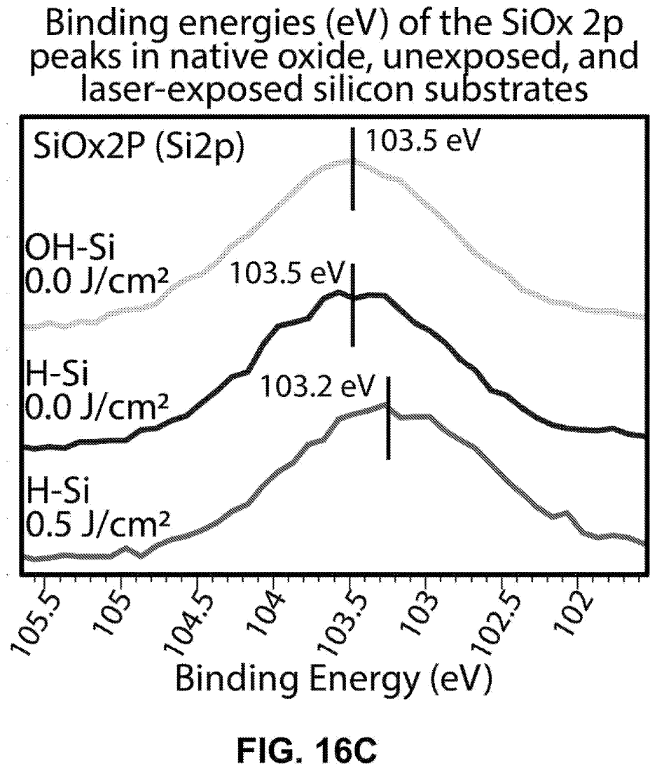

To further evaluate whether the beam imprint observed with SEM was primarily a product of chemical or physical surface transformation, the irradiated H—Si(100) surface was allowed to passively re-oxidize in an ambient laboratory setting for 72 hours. The subsequent XPS and SEM results are shown in FIG. 16A-FIG. 16C and reveal a nebulous picture of how additional oxidation of the laser exposed sites progresses. SEM shows that a change in contrast occurs within the H—Si(100) exposure sites after prolonged exposure to the ambient environment compared to the same surface immediately following laser exposure. This change occurs despite almost identical SEM detection settings, yet still the laser site appears to be charging electrons differently. The darker shade on the 72 hr post exposure sample more closely resembles that of the exposure site observed on the OH—Si(100) surface in FIG. 14A. And although the beam resolutions are still high compared to that of the OH—Si(100) site, one can begin to see fading around the edges of the beam imprints on H—Si(100) 72 hours post exposure. However, the majority of each beam imprint did remain across the 72 hours. Interestingly, after 72 hours of air exposure, the histogram in FIG. 16B shows that the SiOₓ2p XPS signal on H—Si(100) is lower in the irradiated sites (above 0.01 J/cm²) compared to an non-irradiated site. For example, the SiOₓ2p signal measured from the site irradiated with 0.75 J/cm² is about 12.5% less than the signal measured on the non-irradiated site. The O1s signal is also lower on H—Si(100) sites irradiated with at least 0.75 J/cm². This same reduction in SiOₓ2p and O1s signals is not found on laser exposed OH—Si(100) sites, all of which more or less resemble the chemical composition of the corresponding non-irradiated site. Therefore, just as the rate of oxidation on H—Si(100) increased with laser fluence exposure in FIG. 13B-FIG. 13C and FIG. 14B-FIG. 14C, the rate of subsequent passive oxide formation decreases with increasing laser fluence following 72 hours of air exposure. This, in conjunction with the beam imprints still visible but with a change in contrast, may suggest that the original oxide formed on H—Si(100) post exposure may differ chemically from that of oxides generated in air or in a solution phase oxidizer (i.e. Nano-Strip). This reasoning is further validated by the SiOₓ2p XPS spectra in FIG. 16C which shows that the signal measured from a H—Si(100) site irradiated with 0.5 J/cm² is shifted to a lower binding energy by 0.3 eV compared to signals found on both non-irradiated OH—Si(100) and H—Si(100) sites. Thus, it is possible that rather than stoichiometric SiO₂, a slightly different form of oxide is generated using this LAO technique, possibly some derivation of Si₂O₃ which is reported to be 0.9 eV down energy from the SiO₂ signal [B29].

CONCLUSION. Presented here is a methodology for universal patterning of atomic and molecular resists using nanosecond pulsed laser radiation. Specifically, Nd:YAG pulsed laser radiation was employed to increase the rate of oxidation on hydrogen-terminated Si(100) under low vacuum and room temperature conditions. An interval of laser beam energy density (0.25-0.70 J/cm²) was established in which the rate of surface oxidation on H—Si(100) is enhanced, whereas a corresponding OH—Si(100) surface saw minimal oxide growth. Furthermore, XPS demonstrated that the degree of surface oxide content on H—Si(100) increased with energy density and correlated with the formation of small spots (matching the profile of the laser beam) observed with SEM. This imaging was paired with laser fluence mapping to demonstrate the local nature of the oxidizing effect. Atomic force microscopy (AFM) analysis was used to verify that these small spot patterns were primarily due to chemical transformation and not physical alteration below the LIDT. Lastly, ambient stability studies over 72 hours demonstrated that subsequent passive oxidation within the irradiated spots progressed differently than on the surrounding non-irradiated area, indicating that laser radiation grows a different form of oxide (most likely Si₂O₃) than that of stoichiometric SiO₂. From these results it was concluded that pulsed laser exposures of a monoatomic hydrogen-resist layer on Si(100) can promote chemical oxidation of the resist without causing morphology damage to the underlying surface. Such an oxidative patterning technique has the potential to enable universal, in situ patterning of various substrate/resist combinations for ASD manufacturing platforms. On the fundamental level of component structuring and deposition, this technique can enable parallel production of chemo-selective molecular or atomic patterns for self-aligned atomic deposition processes, patterning of ultra-shallow doping or insulating layers, or chemical control of the physical properties of the material interfaces. Pulsed-laser activation can be integrated into the current top-down and future bottom-up manufacturing providing a unified method for controlling chemical composition of opto-electronic interfaces at different stages of the device structuring and integration. Lastly, this technology can also extend the current lithographic patterning with photomasks and polymeric photoresists to the scale of the atomic and molecular layers. Future work will focus on using laser-assisted oxidation to pattern organic monomolecular resists that will extend the selectivity window for AS-ALD processes.

ABBREVIATIONS. Area-selective deposition (ASD), area-selective atomic layer deposition (AS-ALD), hydrogen-terminated silicon (H—Si(100)), hydroxyl-terminated silicon (OH—Si(100)), ultrahigh vacuum (UHV), x-ray photoelectron spectroscopy (XPS), secondary electron microscopy (SEM), scanning tunneling microscopy (STM), atomic force microscopy (AFM)

### REFERENCES

(B1) Semiconductor Industry Association 2015 International Technology Roadmap for Semiconductors (ITRS). 2015. https://www.semiconductors.org/resources/2015-international-technology-roadmap-for-semiconductors-itrs/(accessed.
(B2) (a) Constantinou P ET AL. EUV-induced hydrogen desorption as a step towards large-scale silicon quantum device patterning. Nat Commun 2024, 15 (1). DOI: ARTN 69410.1038/s41467-024-44790-6. (b) Tseng L et al. Resistless EUV lithography: Photon-induced oxide patterning on silicon. Sci Adv 2023, 9 (16). DOI: ARTN eadf599710.1126/sciadv.adf5997.
(B3) (a) Ho J C et al. Controlled nanoscale doping of semiconductors via molecular monolayers. Nat Mater 2008, 7 (1), 62-67. DOI: 10.1038/nmat2058. (b) Veerbeek J et al. Highly doped silicon nanowires by monolayer doping. Nanoscale 2017, 9 (8), 2836-2844. DOI: 10.1039/c6nr07623h. (c) Ye L et al. Controlling the Dopant Dose in Silicon by Mixed-Monolayer Doping. Acs Appl Mater Inter 2015, 7 (5), 3231-3236. DOI: 10.1021/am5079368. (d) Zhang C F et al. Advances in ultrashallow doping of silicon. Adv Phys-X 2021, 6 (1). DOI: Artn 1871407 10.1080/23746149.2020.1871407.
(B4) (a) Raffaelle P R et al. Vapor-Phase Halogenation of Hydrogen-Terminated Silicon(100) Using-Halogen-succinimides. Acs Appl Mater Inter 2023, 15 (47), 55139-55149. DOI: 10.1021/acsami.3c13269. (b) Ogunfowora L A et al. Reactive Vapor-Phase Inhibitors for Area-Selective Depositions at Tunable Critical Dimensions. Acs Appl Mater Inter 2024, 16 (4), 5268-5277. DOI: 10.1021/acsami.3c14821.
(B5) (a) Sánchez-Bodón J et al. Bioactive Coatings on Titanium: A Review on Hydroxylation, Self-Assembled Monolayers (SAMs) and Surface Modification Strategies. Polymers-Basel 2022, 14 (1). DOI: ARTN 16510.3390/polym14010165. (b) Li L N et al. Simulating selective binding of a biological template to a nanoscale architecture: a core concept of a clamp-based binding-pocket-favored N-terminal-domain assembly. Nanoscale 2020, 12 (47), 24214-24227. DOI: 10.1039/dOnr07320b. (c) Piskunen P et al. Biotemplated Lithography of Inorganic Nanostructures (BLIN) for Versatile Patterning of Functional Materials. Acs Appl Nano Mater 2021, 4 (1), 529-538. DOI: 10.1021/acsanm.0c02849.
(B6) Bowers C M et al. Multicomponent Patterning of Indium Tin Oxide. Acs Appl Mater Inter 2012, 4 (8), 3932-3937. DOI: 10.1021/am300768f.
(B7) Wendeln C et al. Modification of Surfaces by Chemical Transfer Printing Using Chemically Patterned Stamps. Langmuir 2013, 29 (8), 2692-2699. DOI: 10.1021/la305024a.
(B8) (a) Shestopalov A A et al. Catalytic Microcontact Printing on Chemically Functionalized H-Terminated Silicon. Langmuir 2010, 26 (3), 1449-1451. DOI: 10.1021/la903465f. (b) Jiang L et al. Investigations on the Adhesive Contact Behaviors between a Viscoelastic Stamp and a Transferred Element in Microtransfer Printing. Coatings 2021, 11 (10). DOI: ARTN 1201 10.3390/coatings11101201. (c) Park J et al. Transfer Printing of Electronic Functions on Arbitrary Complex Surfaces. Acs Nano 2020, 14 (1), 12-20. DOI: 10.1021/acsnano.9b09846.
(B9) (a) Yang Y et al. Direct etching of nano/microscale patterns with both few-layer graphene and high-depth graphite structures by the raster STM electric lithography in the ambient conditions. J Microsc-Oxford 2023, 292 (1), 37-46. DOI: 10.1111/jmi.13224. (b) Dwyer K J et al. STM-Induced Desorption and Lithographic Patterning of Cl—Si(100)-(2×1). J Phys Chem A 2019,123 (50), 10793-10803. DOI: 10.1021/acs.jpca.9b07127.
(B10) (a) Gaevski M E et al. High density submicron features using a laser pattern generator and double patterning. J Vac Sci Technol B 2009, 27 (6), 2742-2744. DOI: 10.1116/1.3263192. (b) Lechthaler B et al. Direct laser interference patterning combined with mask imaging. Opt Laser Technol 2020, 123. DOI: ARTN 105918 10.1016/j.optlastec.2019.105918. (c) Yoo J H et al. Laser-Assisted Tailored Patterning of Au Nanoparticles over an Inch-Sized Area: Implications for Large Aperture Meta-optics. Acs Appl Nano Mater 2022, 5 (7), 10073-10080. DOI: 10.1021/acsanm.2c02590.
(B11) (a) Toulouse A et al. High resolution femtosecond direct laser writing with wrapped lens. Opt Mater Express 2022, 12 (9), 3801-3809. DOI: 10.1364/Ome.468534. (b) Kuts R I et al. Increasing the spatial resolution of direct laser writing by using a non-Gaussian intensity distribution in the writing laser spot. Proc Spie 2022, 12318. DOI: Artn 123180o 10.1117/12.2643710.
(B12) Green M L et al. Ultrathin (&lt; 4 nm) SiO and Si—O—N gate dielectric layers for silicon microelectronics: Understanding the processing, structure, and physical and electrical limits. J Appl Phys 2001, 90 (5), 2057-2121. DOI: Doi 10.1063/1.1385803.
(B13) (a) Cottom J et al. From Jekyll to Hyde and Beyond: Hydrogen's Multifaceted Role in Passivation, H-Induced Breakdown, and Charging of Amorphous Silicon Nitride. J Phys Chem Lett 2024, 15 (3), 840-848. DOI: 10.1021/acs.jpclett.3c03376. (b) Hamoudi A M et al. Multicrystalline Silicon Passivation by Hydrogen and Oxygen-Rich Porous Silicon Layer for Photovoltaic Cells Applications. Iran J Mater Sci Eng 2023, 20 (2). DOI: ARTN 2908 10.22068/ijmse.2908. (c) Sun Z Y et al. Study of the Hydrogen Passivation Effect of Low-Temperature-Deposited Amorphous Silicon Layers on SiGe Solar Cells Grown on a Silicon Substrate. Acs Appl Energ Mater 2023, 6 (23), 12064-12071. DOI: 10.1021/acsaem.3c02283.
(B14) Grayson A C R et al. A BioMEMS review: MEMS technology for physiologically integrated devices. P Ieee 2004, 92 (1), 6-21. DOI: 10.1109/Jproc.2003.820534.
(B15) Aygun G et al. Oxidation of Si surface by a pulsed Nd:YAG laser. J Phys D Appl Phys 2004, 37 (11), 1569-1575. DOI: Pii S0022-3727(04)78415-610.1088/0022-3727/37/11/011.
(B16) Kailath B J et al. Growth of ultra-thin SiO by laser-induced oxidation. Semicond Sci Tech 2009, 24 (10). DOI: Artn 10501110.1088/0268-1242/24/10/105011.
(B17) Osipov A V et al. Kinetics of laser-induced oxidation of silicon near room temperature. Appl Phys a-Mater 2006, 82 (2), 275-280. DOI: 10.1007/s00339-005-3415-x.
(B18) Jia Z C et al. Thermal process of a silicon wafer under a CW laser and 100-10000 Hz pulsed laser irradiation. Appl Optics 2023, 62 (36), 9577-9582. DOI: 10.1364/Ao.501947.
(B19) (a) Behrenberg D et al. Photothermal laser processing of thin silicon nanoparticle films: on the impact of oxide formation on film morphology. Appl Phys a-Mater 2012, 106 (4), 853-861. DOI: 10.1007/s00339-012-6779-8. (b) An H J et al. Study on surface thermal oxidation of silicon carbide irradiated by pulsed laser using reactive molecular dynamics. J Chem Phys 2023, 158 (10). DOI: Artn 104702 10.1063/5.0137778.
(B20) Methaapanon R et al. Comparative Study of Titanium Dioxide Atomic Layer Deposition on Silicon Dioxide and Hydrogen-Terminated Silicon. JPhys Chem C 2010, 114 (23), 10498-10504. DOI: 10.1021/jp1013303.
(B21) Wilhelmi O et al. Proton and electron impact on molecular and atomic oxygen: I.: High resolution fluorescence spectra in the visible and VUV spectral range and emission cross-sections for dissociative ionisation and excitation of O. Eur Phys J D 2000, 11 (1), 79-90. DOI: Doi 10.1007/P100011154.
(B22) Nayar V et al. Low-Temperature Oxidation of Crystalline Silicon Using Excimer Laser Irradiation. Appl Surf Sci 1989, 36 (1-4), 134-140. DOI: Doi 10.1016/0169-4332(89)90906-9.
(B23) Jin Y G et al. Mechanism for the enhanced diffusion of charged oxygen ions in SiO. Phys Rev Lett 2001, 86 (9), 1793-1796. DOI: DOI 10.1103/PhysRevLett.86.1793.
(B24) Liu Y A et al. One-Step Femtosecond Laser Irradiation of Single-Crystal Silicon: Evolution of Micro-Nano Structures and Damage Investigation. Mater Design 2023, 225. DOI: ARTN 11144310.1016/j.matdes.2022.111443.
(B25) Kuladeep R et al. Optical, structural and morphological studies of nanostructures fabricated on silicon surface by femtosecond laser irradiation. J Mater Sci 2022, 57(3), 1863-1880. DOI: 10.1007/s10853-021-06712-5.
(B26) Gibbons J F. Applications of Scanning Cw Lasers and Electron-Beams in Silicon Technology. Jpn J Appl Phys 1980, 19, 121-128. DOI: Doi 10.7567/Jjaps.19s1.121.
(B27) Boyd I W. Laser-Enhanced Oxidation of Si. Appl Phys Lett 1983, 42 (8), 728-730. DOI: Doi 10.1063/1.94041.
(B28) (a) Tsetseris L et al. Physical mechanisms of negative-bias temperature instability. Appl Phys Lett 2005, 86 (14). DOI: Artn 14210310.1063/1.1897075. (b) Fleetwood D M.

Interface traps, correlated mobility fluctuations, and low-frequency noise in metal-oxide-semiconductor transistors. Appl Phys Lett 2023, 122 (17). DOI: Artn 17350410.1063/5.0146549.
(B29) Bashouti M Y et al. Hybrid Silicon Nanowires: From Basic Research to Applied Nanotechnology. Nanowires—Recent Advances 2012, 177-210. DOI: 10.5772/54383.

### EXEMPLARY ASPECTS

In view of the described compositions, devices, systems, and methods, herein below are described certain more particularly described aspects of the inventions. The particularly recited aspects should not, however, be interpreted to have any limiting effect on any different claims containing different or more general teachings described herein or that the “particular” aspects are somehow limited in some way other than the inherent meanings of the language and formulas literally used therein.

Example 1: A method comprising: irradiating a portion of a top surface of a substrate with a laser; wherein the laser has a fluence of from 0.05 to 2.5 J/cm²; wherein the laser has a wavelength of from 190 nm to 2500 nm; and wherein the irradiation comprises a laser pulse, the pulse having a duration of from 200 femtoseconds to 10 nanoseconds.

Example 2: The method of any examples herein, particularly example 1, wherein the portion irradiated with the laser defines a growth surface and the remaining portion (e.g., the non-irradiated portion) comprises a non-growth surface, or wherein the portion irradiated with the laser defines a non-growth surface and the remaining portion (e.g., the non-irradiated portion) comprises a growth surface; and wherein the method further comprises subsequently depositing a first material on the substrate, wherein the first material selectively deposits on the growth surface relative to the non-growth surface; thereby forming a patterned substrate.

Example 3: The method of any examples herein, particularly example 1 or example 2, further comprising cleaning and/or etching the substrate prior to irradiation.

Example 4: The method of any examples herein, particularly examples 2-3, further comprising: irradiating a portion of the patterned substrate with the laser; wherein the portion irradiated with the laser defines a growth surface and the remaining portion (e.g., the non-irradiated portion) comprises a non-growth surface, or wherein the portion irradiated with the laser defines a non-growth surface and the remaining portion (e.g., the non-irradiated portion) comprises a growth surface; and subsequently depositing a second material on the substrate, wherein the second material selectively deposits on the growth surface relative to the non-growth surface.

Example 5: The method of any examples herein, particularly example 4, wherein the irradiated portion of the patterned substrate comprises the top surface of the substrate.

Example 6: The method of any examples herein, particularly example 4, wherein the irradiated portion of the patterned substrate comprises the first material.

Example 7: The method of any examples herein, particularly examples 2-6, wherein the first material and the second material are the same.

Example 8: The method of any examples herein, particularly examples 2-6, wherein the first material and the second material are different.

Example 9: The method of any examples herein, particularly examples 2-8, wherein the non-growth surface is substantially free of the first material and/or the second material.

Example 10: The method of any examples herein, particularly examples 2-9, wherein the first material and/or the second material comprises a metal, an oxide such as a metal oxide, an organic resist, a semiconductor, or a combination thereof.

Example 11: The method of any examples herein, particularly example 10, wherein the organic resist comprises an atomic or molecular resist.

Example 12: The method of any examples herein, particularly examples 2-11, wherein depositing the first material and/or the second material comprises chemical vapor deposition (CVD), atomic layer deposition (ALD), or a combination thereof.

Example 13: The method of any examples herein, particularly examples 1-12, wherein the irradiated portion is oxidized by the laser.

Example 14: The method of any examples herein, particularly examples 1-13, wherein the laser has a fluence of from 0.1 to 1 J/cm², from 0.25 to 0.7 J/cm², or from 0.5 to 0.7 J/cm².

Example 15: The method of any examples herein, particularly examples 1-14, wherein the laser has a wavelength of from 250 nm to 1000 nm, from 250 to 750 nm, from 250 to 500 nm, from 300 to 400 nm, or from 325 to 375 nm.

Example 16: The method of any examples herein, particularly examples 1-15, wherein the laser has a fluence of from 0.5 to 0.7 J/cm² and a wavelength of from 250 to 500 nm, such as a wavelength of from 325 to 375 nm.

Example 17: The method of any examples herein, particularly examples 1-16, wherein the pulse has a duration of from 1 to 10 nanoseconds (ns), from 2 ns to 8 ns, from 3 ns to 7 ns, or from 4 ns to 6 ns.

Example 18: The method of any examples herein, particularly examples 1-17, wherein the laser has a fluence of from 0.5 to 0.7 J/cm² and the pulse has a duration of from 1 to 10 nanoseconds.

Example 19: The method of any examples herein, particularly examples 1-18, wherein the laser has a wavelength of from 250 nm to 500 nm, such as a wavelength from 325 to 375 nm, and the pulse has a duration of from 1 to 10 nanoseconds.

Example 20: The method of any examples herein, particularly examples 1-19, wherein the laser has a fluence of from 0.5 to 0.7 J/cm² and a wavelength of from 250 nm to 500 nm, such as a wavelength from 325 to 375 nm, and the pulse has a duration of from 1 to 10 nanoseconds.

Example 21: The method of any examples herein, particularly examples 1-20, wherein the irradiation has an absorption depth of from 1 nm to 10 nm.

Example 22: The method of any examples herein, particularly examples 1-21, wherein the irradiation is below the laser-induced damage threshold.

Example 23: The method of any examples herein, particularly examples 1-22, wherein the method is performed at a temperature of from 0 to 400° C., from 0° C. to 200° C., from 0° C. to 100° C., or from 10° C. to 50° C.

Example 24: The method of any examples herein, particularly examples 1-23, wherein the method is performed at room temperature.

Example 25: The method of any examples herein, particularly examples 1-24, wherein the substrate has a temperature of from 0 to 400° C., from 0° C. to 200° C., from 0° C. to 100° C., or from 10° C. to 50° C.

Example 26: The method of any examples herein, particularly examples 1-25, wherein the substrate is at room temperature.

Example 27: The method of any examples herein, particularly examples 1-26, wherein the temperature of the substrate is not substantially changed by the irradiation (e.g., wherein the irradiation does not substantially heat the substrate).

Example 28: The method of any examples herein, particularly examples 1-27, wherein the method is performed under vacuum.

Example 29: The method of any examples herein, particularly examples 1-28, wherein the method is performed at a pressure of from 1×10⁻⁷ Pascals (Pa) to 500 Pa.

Example 30: The method of any examples herein, particularly examples 1-29, wherein the method is performed at a pressure of 1×10⁻⁷ Pa to 0.1 Pa, 1×10⁻⁷ Pa to 1×10⁻³ Pa, or from 1×10⁻⁷ Pa to 1×10⁻⁵ Pa.

Example 31: The method of any examples herein, particularly examples 1-30, wherein the method is performed at room temperature and under vacuum.

Example 32: The method of any examples herein, particularly examples 1-31, wherein the substrate comprises silicon.

Example 33: The method of any examples herein, particularly examples 1-32, wherein the substrate comprises Si(100), Si(110), Si(111), or Si(110).

Example 34: The method of any examples herein, particularly examples 1-33, wherein the substrate comprises Si(100).

Example 35: The method of any examples herein, particularly examples 1-34, wherein the top surface of the substrate comprises H—Si(100).

Example 36: The method of any examples herein, particularly examples 1-35, wherein the irradiated portion of the top surface of the substrate is oxidized by the laser.

Example 37: The method of any examples herein, particularly examples 1-36, wherein the irradiated portion of the top surface of the substrate comprises OH—Si(100).

Example 38: The method of any examples herein, particularly examples 1-37, further comprising wet chlorination of the substrate before or after irradiation, but before deposition and after cleaning/etching.

Example 39: The method of any examples herein, particularly example 38, wherein the top surface of the substrate comprises Cl—Si(100).

Example 40: The method of any examples herein, particularly example 38 or example 39, wherein the irradiated portion of the top surface of the substrate comprises ClₓO_{y}—Si(100).

Example 41: The method of any examples herein, particularly examples 1-40, wherein the method comprises area-selective atomic layer deposition, atomic layer etching, scanning tunneling microscopy (STM), extreme UV lithography, or a combination thereof.

Example 42: A patterned substrate made by the method of any examples herein, particularly examples 1-41.

Example 43: An article of manufacture comprising the patterned substrate of any examples herein, particularly example 42.

Example 44: The article of any examples herein, particularly example 43, wherein the article comprises an electronic device, a photonic device, an optical device, an optoelectronic device, or a combination thereof.

The methods, devices, and compositions of the appended claims are not limited in scope by the specific methods, devices, and compositions described herein, which are intended as illustrations of a few aspects of the claims and any methods, devices, and compositions that are functionally equivalent are within the scope of this disclosure. Various modifications of the methods, devices, and compositions in addition to those shown and described herein are intended to fall within the scope of the appended claims. Further, while only certain representative methods, compositions, and aspects of these methods, devices, and compositions are specifically described, other methods, devices, and compositions and combinations of various features of the methods, devices, and compositions are intended to fall within the scope of the appended claims, even if not specifically recited. Thus a combination of steps, elements, components, or constituents can be explicitly mentioned herein; however, all other combinations of steps, elements, components, and constituents are included, even though not explicitly stated.

1. A method comprising:
irradiating a portion of a top surface of a substrate with a laser;
wherein the laser has a fluence of from 0.05 to 2.5 J/cm²;
wherein the laser has a wavelength of from 190 nm to 2500 nm; and
wherein the irradiation comprises a laser pulse, the pulse having a duration of from 200 femtoseconds to 10 nanoseconds,
wherein the portion irradiated with the laser defines a growth surface and the remaining portion comprises a non-growth surface, or wherein the portion irradiated with the laser defines a non-growth surface and the remaining portion comprises a growth surface; and
wherein the method further comprises subsequently depositing a first material on the substrate, wherein the first material selectively deposits on the growth surface relative to the non-growth surface;
thereby forming a patterned substrate.

2. (canceled)

3. The method of claim 1, further comprising cleaning and/or etching the substrate prior to irradiation.

4. The method of claim 1, further comprising:
irradiating a portion of the patterned substrate with the laser;
wherein the portion irradiated with the laser defines a growth surface and the remaining portion comprises a non-growth surface, or wherein the portion irradiated with the laser defines a non-growth surface and the remaining portion comprises a growth surface; and
subsequently depositing a second material on the substrate, wherein the second material selectively deposits on the growth surface relative to the non-growth surface.

5. The method of claim 4, wherein the irradiated portion of the patterned substrate comprises the top surface of the substrate.

6. The method of claim 4, wherein the irradiated portion of the patterned substrate comprises the first material.

7. (canceled)

8. (canceled)

9. The method of claim 1, wherein the non-growth surface is substantially free of the first material.

10. The method of claim 1, wherein the first material comprises a metal, an oxide, an organic resist, a semiconductor, or a combination thereof.

11. The method of claim 1, wherein the first material comprises an organic resist and the organic resist comprises an atomic or molecular resist.

12. The method of claim 1, wherein depositing the first material comprises chemical vapor deposition (CVD), atomic layer deposition (ALD), or a combination thereof.

13. The method of claim 1, wherein the irradiated portion is oxidized by the laser.

14. The method of claim 1, wherein the laser has a fluence of from 0.1 to 1 J/cm².

15. The method of claim 1, wherein the laser has a wavelength of from 250 nm to 1000 nm.

16. (canceled)

17. The method of claim 1, wherein the pulse has a duration of from 1 to 10 nanoseconds (ns).

18. (canceled)

19. (canceled)

20. (canceled)

21. The method of claim 1, wherein the irradiation has an absorption depth of from 1 nm to 10 nm.

22. The method of claim 1, wherein the irradiation is below the laser-induced damage threshold.

23. (canceled)

24. (canceled)

25. (canceled)

26. (canceled)

27. The method of claim 1, wherein the temperature of the substrate is not substantially changed by the irradiation.

28. (canceled)

29. (canceled)

30. (canceled)

31. (canceled)

32. The method of claim 1, wherein the substrate comprises silicon.

33. (canceled)

34. (canceled)

35. (canceled)

36. (canceled)

37. (canceled)

38. The method of claim 1, further comprising wet chlorination of the substrate before or after irradiation, but before deposition and after cleaning/etching.

39. (canceled)

40. (canceled)

41. (canceled)

42. A patterned substrate made by the method of claim 1.

43. An article of manufacture comprising the patterned substrate of claim 42, wherein the article comprises an electronic device, a photonic device, an optical device, an optoelectronic device, or a combination thereof.

44. (canceled)
